(19) United States
(12) Patent Application Publication
(10) Pub. No.: US 2019/0280644 A1
(43) Pub. Date: Sep. 12, 2019

(54) SOLAR CELL DEVICE

(71) Applicant: Kyocera Corporation, Kyoto (JP)

(72) Inventors: Mitsuo Yamashita, Higashiomi-shi (JP); Yuta Nishio, Yasu-shi (JP)

(21) Appl. No.: 16/421,064

(22) Filed: May 23, 2019

Related U.S. Application Data
(63) Continuation of application No. PCT/JP2017/042351, filed on Nov. 27, 2017.

(30) Foreign Application Priority Data
Nov. 29, 2016 (JP) 2016-231346

(51) Int. Cl. H02S 30/10; H01L 31/05; H01L 31/048; H02S 20/23

(52) U.S. Cl. CPC H02S 30/10; H02S 20/23; H01L 31/048; H01L 31/0508

(57) ABSTRACT

The solar cell device includes a solar cell module, a first member, a second member, and an elastic member. The solar cell module has a front surface and a back surface opposite the front surface, the front surface being convexly curved. The first member supports a first outer edge portion in a first direction along the back surface of the solar cell module. The second member supports a second outer edge portion opposite the first outer edge portion in the first direction of the solar cell module. The elastic member includes an elastic body and is in contact with or in proximity to the back surface. The solar cell module includes a photoelectric converter, a first protector covering the photoelectric converter from a front surface side, and a second protector covering the photoelectric converter from a back surface side.

### CROSS-REFERENCE TO RELATED APPLICATIONS

The present application is a continuation based on PCT Application No. PCT/JP2017/042351 filed on Nov. 27, 2017, which claims the benefit of Japanese Application No. 2016-231346, filed on Nov. 29, 2016. PCT Application No. PCT/JP2017/042351 is entitled “SOLAR CELL DEVICE”, and Japanese Application No. 2016-231346 is entitled “SOLAR CELL DEVICE”. The contents of which are incorporated by reference herein in their entirety.

### FIELD

Embodiments of the present disclosure relate generally to solar cell devices.

### BACKGROUND

A solar cell device including one or more solar cell modules is required to be reduced in weight from a viewpoint of reduction of the load on an installation object such as a building, and reduction of the workload on an installer when the installer installs the solar cell module on the installation object.

Methods of reducing the weight of the solar cell module include thinning of a glass plate that protects the surface of the solar cell module, for example. However, the rigidity of the glass plate is reduced with the reduction in thickness. In this case, the solar cell module is likely to be curved so that a light-receiving surface is concavely recessed by its own weight. For this reason, rainwater is likely to gather in the recess of the light-receiving surface. At this time, for example, evaporation of the rainwater gathered in the recess will cause the glass plate to have glass surface turbidity and adhesion of dirt, which may reduce the output of the solar cell module.

Therefore, it has been proposed to curve the solar cell module in advance such that the light-receiving surface is convexly shaped.

### SUMMARY

A solar cell device is disclosed.

In one embodiment, a solar cell device comprises a solar cell module, a first member, a second member, and an elastic member. The solar cell module has a front surface and a back surface opposite the front surface, the front surface being convexly curved. The first member is supporting a first outer edge portion in a first direction along the back surface of the solar cell module. The second member is supporting a second outer edge portion opposite the first outer edge portion in the first direction of the solar cell module. The elastic member includes an elastic body, and is in contact with the back surface or in proximity to the back surface. The solar cell module includes a photoelectric converter, a first protector covering the photoelectric converter from a front surface side, and a second protector covering the photoelectric converter from a back surface side.

### BRIEF DESCRIPTION OF THE DRAWINGS

FIG. 1 illustrates an exploded perspective view showing a part of the configuration of an example of a solar cell device according to a first embodiment of the present disclosure.

FIG. 2 illustrates a plan view showing the configuration of a front side of an example of a solar cell module.

FIG. 3 illustrates a virtual cut section of the solar cell module taken along line of FIG. 2.

FIG. 4 schematically illustrates the solar cell module in a curved state.

FIG. 5 illustrates a cross-sectional view schematically showing an example of a curvature aspect of a part of the solar cell module.

FIG. 6 illustrates a plan view for explaining a stress applied to the solar cell.

FIG. 7 illustrates an exploded perspective view showing a part of the configuration of an example of a solar cell device according to a second embodiment of the present disclosure.

FIG. 8 illustrates a plan view showing the configuration of an example of a solar cell device according to a third embodiment of the present disclosure.

FIG. 9 illustrates a back view showing the configuration of an example of the solar cell device according to the third embodiment.

FIG. 10 illustrates a virtual cut section of the solar cell device taken along line X-X in FIGS. 8 and 9.

FIG. 11 illustrates a virtual cross-section of the solar cell device taken along line XI-XI in FIGS. 8 and 9.

FIG. 12 illustrates a virtual cut section of the solar cell device taken along line XII-XII in FIGS. 8 and 9.

FIG. 13 illustrates an exploded perspective view showing an example of the configuration of a part of the solar cell device.

FIG. 14 illustrates an exploded perspective view showing an example of a part of the configuration of a solar cell device according to a fourth embodiment of the present disclosure.

FIG. 15A illustrates a cross-sectional view showing a virtual cross-section corresponding to the virtual cross-section taken along the line XI-XI in FIGS. 8 and 9 in the configuration of the example of the solar cell device according to the fourth embodiment.

FIG. 15B illustrates a cross-sectional view showing a virtual cross-section corresponding to a virtual cross-section taken along line XVb-XVb in FIGS. 8 and 9 in the configuration of the example of the solar cell device according to the fourth embodiment.

FIG. 16 illustrates a perspective view showing the configuration of an example of an auxiliary member and an elastic member according to a fifth embodiment of the present disclosure.

FIG. 17 illustrates a virtual cut section corresponding to the virtual cut section taken along the line X-X in FIGS. 8 and 9 in the configuration of an example of a solar cell device according to the fifth embodiment.

FIG. 18 illustrates a perspective view showing the configuration of an example of an auxiliary member and an elastic member according to a variation of the fifth embodiment.

FIG. 19 illustrates a virtual cut section corresponding to the virtual cut section taken along the line in FIG. 2 in the configuration of an example of a solar cell device according to a sixth embodiment of the present disclosure.

FIG. 20 illustrates a virtual cut section corresponding to the virtual cut section taken along the line XII-XII in FIGS. 8 and 9 in the configuration of an example of the solar cell device according to the sixth embodiment.

FIG. 21 illustrates a exploded view showing a virtual cut section corresponding to a virtual cut section taken along line XXI-XXI in FIGS. 8 and 9 in the configuration of an example of a solar cell device according to a seventh embodiment of the present disclosure.

FIG. 22 illustrates a virtual cut section corresponding to the virtual cut section taken along the line XXI-XXI in FIGS. 8 and 9 in the configuration of an example of the solar cell device according to the seventh embodiment.

### DETAILED DESCRIPTION

A solar cell device including one or more solar cell modules is required to be reduced in weight from a viewpoint of reduction of the load on an installation object such as a building, and reduction of the workload on an installer when the installer installs the solar cell module on the installation object. For this reason, it is conceivable to reduce the weight of the solar cell device by, for example, thinning the glass plate that protects the surface of the solar cell module.

However, when the glass plate is thinned, the rigidity of the glass plate is reduced. For this reason, the solar cell module may be curved so that the light-receiving surface is concavely shaped by its own weight. In this case, for example, rainwater is likely to gather in the recess of the light-receiving surface. In this state, for example, repeated evaporation of the rainwater gathered in the recess will cause the light-receiving surface to have glass surface turbidity and adhesion of dirt. As a result, the translucency of the light-receiving surface side of the solar cell module will be reduced, which may reduce the output of the solar cell module. Therefore, it is conceivable to convexly curve in advance the light-receiving surface of the solar cell module.

However, for example, snow accumulated on the solar cell module may apply a relatively large load to the light-receiving surface. In this case, even when the light-receiving surface of the solar cell module has been convexly curved in advance, the light-receiving surface may be concavely curved. At this time, for example, even if the load due to the accumulated snow on the light-receiving surface is released, the solar cell module may not return to the initial state where the light-receiving surface is convexly curved. As a result, for example, glass surface turbidity and adhesion of dirt to the light-receiving surface may cause the translucency on the light-receiving surface side of the solar cell module to be reduced. As a result, the long-term reliability of the solar cell module may be reduced.

Hence, the inventors of the present disclosure have created a technique with which the solar cell device including one or more solar cell modules can return to the initial state when the load is released even if the light-receiving surface is concavely shaped in response to a load from the initial state where the light-receiving surface is convexly curved. In other words, the inventors of the present disclosure have created a technique capable of achieving weight reduction and long-term reliability improvement for a solar cell device including one or more solar cell modules.

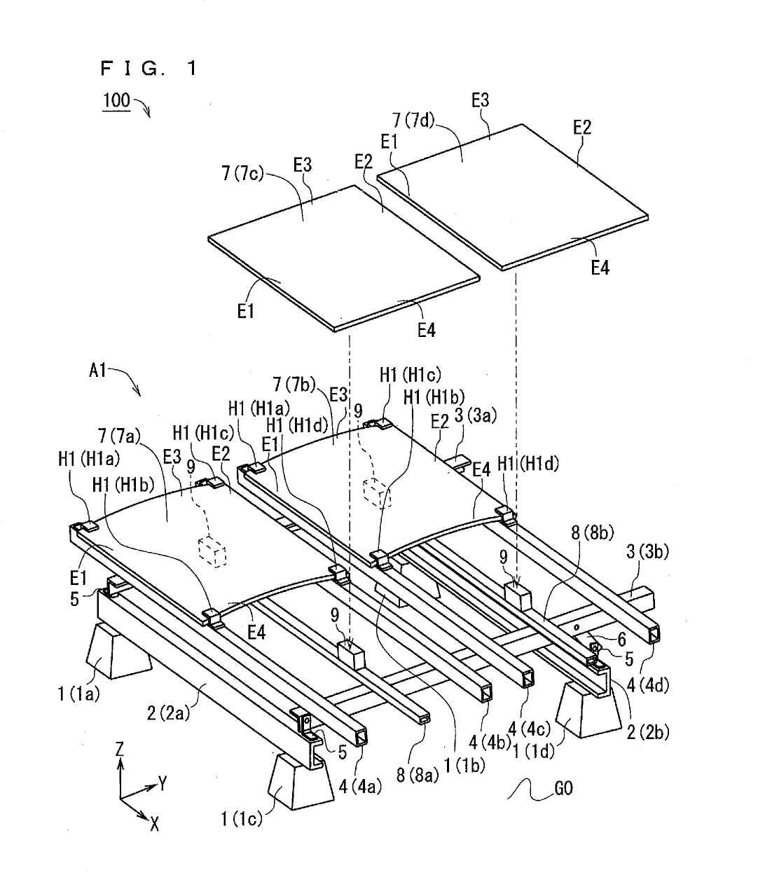

Hereinafter, regarding the technique, various embodiments will be described with reference to the drawings. In the drawings, parts that have the same configuration and function are given the same reference numerals, and redundant explanations will be omitted in the following description. The drawings are shown schematically. In FIGS. 1 to 22, a right-handed XYZ coordinate system is given. In the XYZ coordinate system, the direction along the long side of a front surface Ifs of a solar cell module 7 is a +X direction, the direction along the short side of the front surface Ifs of the solar cell module 7 is a +Y direction, and the direction orthogonal to both the direction +X and the direction +Y direction is a +Z direction.

### 1. First Embodiment

### 1-1. Solar Cell Device

A solar cell device 100 according to the first embodiment will be described with reference to FIGS. 1 to 6. In the first embodiment, the solar cell device 100 has a structure (also referred to as a solar cell array) μl where a plurality of the solar cell modules 7 are positioned in a state of being arrayed. As shown in FIG. 1, the solar cell device 100 includes, for example, a plurality of foundation blocks 1, a plurality of lateral rail members 2, a plurality of longitudinal rail members 3, a plurality of supporting members 4, the plurality of solar cell modules 7, a plurality of auxiliary members 8, and a plurality of elastic members 9.

The foundation block 1 is positioned in a state of supporting the solar cell array μl, for example. The foundation block 1 is positioned, for example, on an object (also referred to as an installation object) G0 on which the solar cell array μl is installed. The installation object G0 is, for example, the ground, the roof of a building or the like. In the example of FIG. 1, four foundation blocks 1 are positioned on the installation object G0. Here, the four foundation blocks 1 are positioned at the four vertices of a virtual rectangle on the installation object G0. The four foundation blocks 1 include a first foundation block 1a, a second foundation block 1b, a third foundation block 1c, and a fourth foundation block 1d. The first foundation block 1a and the second foundation block 1b are arrayed in the +Y direction in the order of this description. The first foundation block 1a and the third foundation block 1c are arrayed in the +X direction in the order of this description. The third foundation block 1c and the fourth foundation block 1d are arrayed in the +Y direction in the order of this description. The second foundation block 1b and the fourth foundation block 1d are arrayed in the +X direction in the order of this description. As a material of the foundation block 1, concrete or the like is adopted in consideration of weather resistance, high strength, and low price, for example.

The lateral rail member 2 is a member positioned in a state of bridging between the two foundation blocks 1 arrayed in the X direction. In the example of FIG. 1, two long linear lateral rail members 2 are present. The two lateral rail members 2 include a first lateral rail member 2a and a second lateral rail member 2b. Here, the first lateral rail member 2a is positioned over an area from the first foundation block 1a to the third foundation block 1c. In addition, the second lateral rail member 2b is positioned over an area from the second foundation block 1b to the fourth foundation block 1d. In other words, each of the two lateral rail members 2 is parallel to an X axis, and the two lateral rail members 2 are in a state of being arrayed in the +Y direction. The lateral rail member 2 is positioned in a state of being fixed to the foundation block 1 with, for example, a metal fitting, a screw and the like.

The longitudinal rail member 3 is a member positioned in a state of bridging between the two lateral rail members 2 arrayed in the Y direction. In the example of FIG. 1, two long linear longitudinal rail members 3 are present. The two longitudinal rail members 3 include a first longitudinal rail member 3a and a second longitudinal rail member 3b.

Here, the first longitudinal rail member 3a is positioned over an area from the first lateral rail member 2a to the second lateral rail member 2b, between regions facing in the +Z direction at parts present closer to the ends facing in a −X direction than to the ends facing in the +X direction. Here, the first longitudinal rail member 3a is positioned in a state of being fixed to the first lateral rail member 2a with, for example, a fixing metal fitting 5 or the like. In this case, for example, the fixing metal fitting 5 is positioned in a state of being fixed to the first lateral rail member 2a with a screw or the like, and the first longitudinal rail member 3a is further positioned in a state of being fixed to the fixing metal fitting 5 with a screw or the like. Here, the first longitudinal rail member 3a is positioned in a state of being fixed to the second lateral rail member 2b with, for example, the fixing metal fitting 5 and an angle adjusting member 6 or the like. In this case, for example, the fixing metal fitting 5 is positioned in a state of being fixed to the second lateral rail member 2b with a screw or the like. For example, the angle adjusting member 6 is further positioned in a state of being fixed to the fixing metal fitting 5 with a screw or the like. Furthermore, for example, the first longitudinal rail member 3a is positioned in a state of being fixed to the angle adjusting member 6 with a screw or the like. At this time, the first longitudinal rail member 3a is in a state of being inclined to the installation object G0 at an angle corresponding to the length of the angle adjusting member 6.

Here, the second longitudinal rail member 3b is positioned over an area from the first lateral rail member 2a to the second lateral rail member 2b, between regions facing in the +Z direction at parts present closer to the ends facing in the +X direction than to the ends facing in the −X direction. Here, the second longitudinal rail member 3b is positioned in a state of being fixed to the first lateral rail member 2a with, for example, the fixing metal fitting 5 or the like. In this case, for example, the fixing metal fitting 5 is positioned in a state of being fixed to the first lateral rail member 2a with a screw or the like. The second longitudinal rail member 3b is further positioned in a state of being fixed to the fixing metal fitting 5 with a screw or the like. Here, the second longitudinal rail member 3b is positioned in a state of being fixed to the second lateral rail member 2b with, for example, the fixing metal fitting 5 and the angle adjusting member 6 or the like. In this case, for example, the fixing metal fitting 5 is positioned in a state of being fixed to the second lateral rail member 2b with a screw or the like. For example, the angle adjusting member 6 is further positioned in a state of being fixed to the fixing metal fitting 5 with a screw or the like. Furthermore, for example, the second longitudinal rail member 3b is positioned in a state of being fixed to the angle adjusting member 6 with a screw or the like. At this time, the second longitudinal rail member 3b is in a state of being inclined to the installation object G0 at an angle corresponding to the length of the angle adjusting member 6.

Here, the two longitudinal rail members 3 are parallel to each other, perpendicular to the X axis, and inclined to an XY plane.

The supporting member 4 is positioned in a state of supporting the solar cell module 7, for example. In the example of FIG. 1, four long supporting members 4 are present. The four long supporting members 4 include a first supporting member 4a, a second supporting member 4b, a third supporting member 4c, and a fourth supporting member 4d. Here, each of the first supporting member 4a, the second supporting member 4b, the third supporting member 4c, and the fourth supporting member 4d is positioned in a state of bridging over an area from the first longitudinal rail member 3a to the second longitudinal rail member 3b. The first supporting member 4a, the second supporting member 4b, the third supporting member 4c, and the fourth supporting member 4d are parallel to the X axis, and are positioned in a state of being arrayed in the order of this description. Each of the supporting members 4 is positioned in a state of being fixed to the first longitudinal rail member 3a and the second longitudinal rail member 3b with, for example, a screw or the like.

Here, a ferrous metal such as stainless steel, a non-ferrous metal such as aluminum or the like is adopted as the material for the lateral rail member 2, the longitudinal rail member 3, the supporting member 4, the fixing metal fitting 5, and the angle adjusting member 6, for example, in consideration of weather resistance, high strength, and low cost.

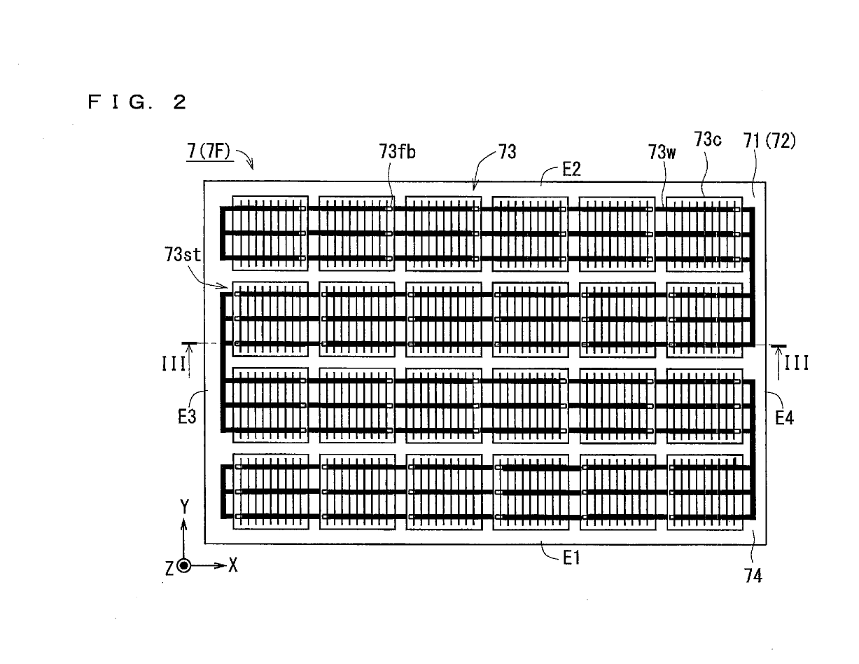

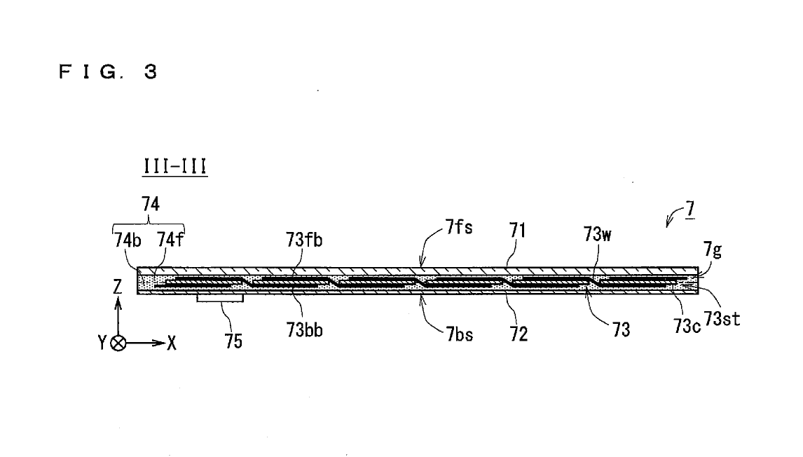

The solar cell module 7 can obtain electrical energy by photoelectric conversion corresponding to the incidence of light such as sunlight, for example. As shown in FIGS. 2 and 3, the solar cell module 7 has a plate-like shape. The solar cell module 7 has, for example, the light-receiving surface (also referred to as the front surface) Ifs that mainly receives light, and a non-light-receiving surface (also referred to as a back surface) lbs opposite the front surface 7fs. Here, the solar cell module 7 includes a lamination where a first protector 71, a front side sealing layer 74f, a photoelectric converter 73, a back side sealing layer 74b, and a second protector 72 are in a state of being laminated, for example, from the front surface Ifs to the back surface 7bs in the order of this description. Here, for example, a surface of the first protector 71 includes the front surface 7fs, and a surface of the second protector 72 includes the back surface 7bs. In the examples of FIGS. 2 and 3, the shape of each of the front surface Ifs and the back surface 7bs is a rectangle.

The first protector 71 is positioned in a state of covering the photoelectric converter 73 from the front surface Ifs side, for example. This allows the first protector 71 to protect the photoelectric converter 73 from the front surface Ifs side. For the first protector 71, a flat plate made of a transparent material having translucency such as glass, for example, is used.

The photoelectric converter 73 includes a plurality of solar cell strings 73st. The plurality of solar cell strings 73st are positioned in a state of being arrayed along a −Y direction as the first direction and the +Y direction as the second direction. Each of the solar cell strings 73st includes a plurality of solar cells 73c arrayed along the −X direction and one or more wires 73w positioned in a state of electrically connecting the plurality of solar cells 73c in series.

In the examples of FIGS. 2 and 3, the photoelectric converter 73 includes four solar cell strings 73st. Each of the solar cell strings 73st includes six solar cells 73c and five sets of wires 73w. Here, one set of wires 73w includes three wires 73w. Each of the one set of wires 73w connects three bus bar electrodes 73fb on the front surface Ifs side of a first solar cell 73c and three bus bar electrodes 73bb on the back surface 7bs side of a second solar cell 73c between the adjacent first solar cell 73c and the second solar cell 73c. Here, the bus bar electrode 73bb on the back surface 73bs side is positioned in a part of the first solar cell 73c facing in the −Z direction as the third direction from the front surface Ifs toward the back surface 7bs. The bus bar electrode 73fb on the front surface 7fs side is positioned in a part of the first solar cell 73c facing in the +Z direction as the opposite direction to the third direction. Each of the bus bar electrodes 73fb and each of the bus bar electrodes 73bb are positioned in a state of extending along the −X direction as a fourth direction orthogonal to the first direction (−Y direction) and the second direction (+Y direction) and along the back surface 7bs. Each of the wires 73w is also positioned in a state of extending along the fourth direction (−X direction). Each of the wires 73w is positioned in a state of being joined to the bus bar electrode 73fb along the longitudinal direction of the bus bar electrode 73fb on the front surface Ifs side, and is positioned in a state of being joined to the bus bar electrode 73bb along the longitudinal direction of the bus bar electrode 73bb on the back surface 7bs side. Each of the wires 73w is positioned in a state of being joined to, for example, the bus bar electrode 73fb on the front surface Ifs side and the bus bar electrode 73bb on the back surface 7bs side with soldering or the like. The adjacent solar cell strings 73st are positioned in a state of being electrically connected with the wire 73w.

For each of the solar cells 73c, for example, a crystalline semiconductor such as crystalline silicon, an amorphous semiconductor such as amorphous silicon, a compound semiconductor using four kinds of elements: copper, indium, gallium, and selenium, a compound semiconductor using cadmium telluride (CdTe), or the like may be applied. The photoelectric converter 73 is in a state of being sealed by, for example, being sandwiched between a front side sealing layer 74f and a back side sealing layer 74b. The front side sealing layer 74f and the back side sealing layer 74b may be made of, for example, a thermosetting resin or the like. In this case, the front side sealing layer 74f and the back side sealing layer 74b constitute an integral sealing member 74. Here, the sealing member 74 is in a state of being filled in a gap 7g between the first protector 71 and the second protector 72, while covering the plurality of solar cell strings 73st.

The second protector 72 is positioned in a state of covering the photoelectric converter 73 from the back surface 7bs side, for example. This allows the second protector 72 to protect the photoelectric converter 73 from the back surface 7bs side. The second protector 72 may be, for example, a flat plate made of a transparent material having translucency such as glass, or a resin sheet. In the first embodiment, the thickness of the first protector 71 is larger than the thickness of the second protector 72. The solar cell 73c using a crystalline semiconductor substrate is less likely to be damaged by a load in the compression direction than in the tensile direction. Therefore, the thickness of the first protector 71 may be larger than the thickness of the second protector 72. This achieves a structure where a load in the compression direction is likely to be applied to the solar cell 73c and the solar cell 73c is less likely to have a crack with the solar cell module 7 being bent convexly upward by the elastic member 9. A load in the compression direction is likely to be applied to the solar cell 73c until the solar cell module 7 becomes a downward convex condition from an upward convex condition by a load further applied to the solar cell module 7.

The solar cell module 7 includes a terminal box 75 positioned on the back surface 7bs. The terminal box 75 can extract the output obtained by the photoelectric converter 73, for example, to the outside. As the terminal box 75, for example, one is adopted that includes a box of a modified polyphenylene ether (modified PPE) resin or a polyphenylene oxide (PPO) resin, a terminal plate positioned in the box, and an output cable for leading electric power to the outside of the box.

In the examples of FIGS. 1 and 2, the solar cell module 7 has the front surface Ifs and the back surface 7bs that are rectangular. In other words, each of the front surface Ifs and the back surface 7bs has four sides. The solar cell module 7 includes a first outer edge portion E1 along a first side of the four sides, a second outer edge portion E2 along a second side of the four sides, a third outer edge portion E3 along a third side of the four sides, and a fourth outer edge portion E4 along a fourth side of the four sides. The first outer edge portion E1 is one outer edge portion in the first direction (−Y direction) along the back surface 7bs of the solar cell module 7. The second outer edge portion E2 is one outer edge portion opposite the first outer edge portion E1 in the first direction (−Y direction) along the back surface 7bs of the solar cell module 7. The third outer edge portion E3 is one outer edge portion in the fourth direction (−X direction) orthogonal to both the first direction (−Y direction) and the second direction (+Y direction) opposite the first direction (−Y direction) of the solar cell module 7 and along the back surface 7bs. The fourth outer edge portion E4 is one outer edge portion opposite the third outer edge portion E3 in the fourth direction (−X direction) along the back surface 7bs of the solar cell module 7.

Each of the solar cell modules 7 is positioned in a state of being supported by the supporting member 4. In the example of FIG. 1, four solar cell modules 7 are positioned in a state of being supported by four supporting members 4. The four solar cell modules 7 include a first solar cell module 7a, a second solar cell module 7b, a third solar cell module 7c, and a fourth solar cell module 7d. Specifically, for example, the first supporting member 4a and the second supporting member 4b are in a state of supporting the first solar cell module 7a and the third solar cell module 7c, which are positioned in a state of being arrayed in the +X direction. For example, the third supporting member 4c and the fourth supporting member 4d are in a state of supporting the second solar cell module 7b and the fourth solar cell module 7d, which are positioned in a state of being arrayed in the +X direction. Here, the combination of the first supporting member 4a and the second supporting member 4b plays a role as a combination of the first member and the second member of the first set. The combination of the third supporting member 4c and the fourth supporting member 4d plays a role as a combination of the first member and the second member of the second set. In the first embodiment, for example, a plurality of metal fittings for holding (also referred to as holding members) H1 are in a state of holding the four solar cell modules 7 on the four supporting members 4.

More specifically, for the first solar cell module 7a, the first supporting member 4a as the first member of the first set is positioned in a state of supporting the first outer edge portion E1 of the first solar cell module 7a. Here, the first outer edge portion E1 is an outer edge portion along one side positioned at an end of the first solar cell module 7a facing in the first direction (−Y direction) along the back surface 7bs of the first solar cell module 7a. Here, a first holding member H1a is positioned in a state of being fixed to the first supporting member 4a with a screw or the like such that, with the first outer edge portion E1 being placed on the first supporting member 4a, the first supporting member 4a and the first holding member H1a are in a state of sandwiching a part present closer to an end facing in the fourth direction (−X direction) than to an end facing in the fifth direction (+X direction) opposite the fourth direction (−X direction) of the first outer edge portion E1. At this time, a second holding member H1b is positioned in a state of being fixed to the first supporting member 4a with a screw or the like such that the first supporting member 4a and the second holding member H1b is in a state of sandwiching a part present closer to the end facing in the fifth direction (+X direction) than to the end facing in the fourth direction (−X direction) of the first outer edge portion E1.

The second supporting member 4b as the second member of the first set is positioned in a state of supporting the second outer edge portion E2 of the first solar cell module 7a. Here, the second outer edge portion E2 is an outer edge portion along one side positioned at an end of the first solar cell module 7a facing in the second direction (+Y direction) along the back surface 7bs of the first solar cell module 7a. Here, on the second supporting member 4b, the second supporting member 4b and a third holding member H1c fixed to the second supporting member 4b with a screw or the like are positioned in a state of sandwiching a part present closer to an end facing in the fourth direction (−X direction) than to an end facing in the fifth direction (+X direction) of the second outer edge portion E2. At this time, the second supporting member 4b and a fourth holding member H1d fixed to the second supporting member 4b with a screw or the like are positioned in a state of sandwiching a part present closer to the end facing in the fifth direction (+X direction) than to the end facing in the fourth direction (−X direction) of the second outer edge portion E2. Here, the first solar cell module 7a is less likely to be broken and shifted when, for example, an elasticity body of silicone rubber or the like is positioned at a part in contact with the first solar cell module 7a among the first holding member H1a, the second holding member H1b, the third holding member H1c, and the fourth holding member H1d.

For the second solar cell module 7b, the third supporting member 4c as the first member of the second set is positioned in a state of supporting the first outer edge portion E1 of the second solar cell module 7b. Here, the first outer edge portion E1 is an outer edge portion along one side positioned at an end of the second solar cell module 7b facing in the first direction (−Y direction) along the back surface 7bs of the second solar cell module 7b. Here, on the third supporting member 4c, the third supporting member 4c and the first holding member H1a fixed to the third supporting member 4c with a screw or the like are positioned in a state of sandwiching a part present closer to an end facing in the fourth direction (−X direction) than to an end facing in the fifth direction (+X direction) of the first outer edge portion E1. At this time, the third supporting member 4c and the second holding member H1b fixed to the third supporting member 4c with a screw or the like are positioned in a state of sandwiching a part present closer to an end facing in the fifth direction (+X direction) than to an end facing in the fourth direction (−X direction) of the first outer edge portion E1.

In addition, the fourth supporting member 4d as the second member of the second set is positioned in a state of supporting the second outer edge portion E2 of the second solar cell module 7b. Here, the second outer edge portion E2 is an outer edge portion along one side positioned at an end of the second solar cell module 7b facing in the second direction (+Y direction) along the back surface 7bs of the second solar cell module 7b. Here, on the fourth supporting member 4d, the fourth supporting member 4d and the third holding member H1c fixed to the fourth supporting member 4d with a screw or the like are positioned in a state of sandwiching a part present closer to an end facing in the fourth direction (−X direction) than to an end facing in the fifth direction (+X direction) of the second outer edge portion E2. At this time, the fourth supporting member 4d and the fourth holding member H1d fixed to the fourth supporting member 4d with a screw or the like are positioned in a state of sandwiching a part present closer to an end facing in the fifth direction (+X direction) than to an end facing in the fourth direction (−X direction) of the second outer edge portion E2.

Also for the third solar cell module 7c, as for the first solar cell module 7a, the first supporting member 4a as the first member of the first set is positioned in a state of supporting the first outer edge portion E1 of the third solar cell module 7c. Here, the first outer edge portion E1 is an outer edge portion along one side positioned at an end of the third solar cell module 7c facing in the first direction (−Y direction) along the back surface 7bs of the third solar cell module 7c. In addition, the second supporting member 4b as the second member of the first set is positioned in a state of supporting the second outer edge portion E2 of the third solar cell module 7c. Here, the second outer edge portion E2 is an outer edge portion along one side positioned at an end of the third solar cell module 7c facing in the second direction (+Y direction) along the back surface 7bs of the third solar cell module 7c.

Also for the fourth solar cell module 7d, as for the second solar cell module 7b, the third supporting member 4c as the first member of the second set is positioned in a state of supporting the first outer edge portion E1 of the fourth solar cell module 7d. Here, the first outer edge portion E1 is an outer edge portion along one side positioned at an end of the fourth solar cell module 7d facing in the first direction (−Y direction) along the back surface 7bs of the fourth solar cell module 7d. Further, the fourth supporting member 4d as the second member of the second set is positioned in a state of supporting the second outer edge portion E2 of the fourth solar cell module 7d. Here, the second outer edge portion E2 is an outer edge portion along one side positioned at an end of the fourth solar cell module 7d facing in the second direction (+Y direction) along the back surface 7bs of the fourth solar cell module 7d.

In the solar cell device 100, each of the solar cell modules 7 has the front surface Ifs convexly curved. At this time, water is less likely to gather on the front surface Ifs if, for example, the solar cell module 7 is positioned with the convex front surface Ifs facing upward and the concave back surface 7bs facing downward.

The auxiliary member 8 is a member for assisting the function of the elastic member 9 that curves each of the solar cell modules 7 such that the front surface Ifs is convexly shaped. In the example of FIG. 1, two long auxiliary members 8 are present. The two long auxiliary members 8 include a first auxiliary member 8a and a second auxiliary member 8b. The first auxiliary member 8a is positioned between the first supporting member 4a and the second supporting member 4b in parallel to both the first supporting member 4a and the second supporting member 4b. The second auxiliary member 8b is positioned between the third supporting member 4c and the fourth supporting member 4d in parallel to both the third supporting member 4c and the fourth supporting member 4d. The first auxiliary member 8a and the second auxiliary member 8b are positioned in a state of being fixed with, for example, a screw or the like to the first longitudinal rail member 3a and the second longitudinal rail member 3b.

The elastic member 9 includes at least a part positioned between the auxiliary member 8 and the back surface 7bs of the solar cell module 7. In the example of FIG. 1, the elastic member 9 is positioned between the back surface 7bs of the solar cell module 7 and the auxiliary member 8 for the back surface 7bs of each of the solar cell modules 7. The elastic member 9 includes an elastic body and is present in contact with the back surface 7bs. In this case, for example, even if the solar cell module 7 is curved due to a load of accumulated snow or the like such that the front surface Ifs is concavely shaped, when the load on the front surface Ifs is released, the elastic member 9 causes the elastic force of the elastic body to push the back surface 7bs. As a result, for example, the front surface Ifs of the solar cell module 7 can return to a convex condition. In this manner, rainwater becomes less likely to gather on the front surface Ifs of the solar cell module 7. This makes it less likely to cause the problem that the translucency on the front surface Ifs side of the solar cell module 7 decreases due to the evaporation of water gathered on the front surface 7fs, for example. Accordingly, it is possible to reduce the weight and improve the long-term reliability of the solar cell device 100.

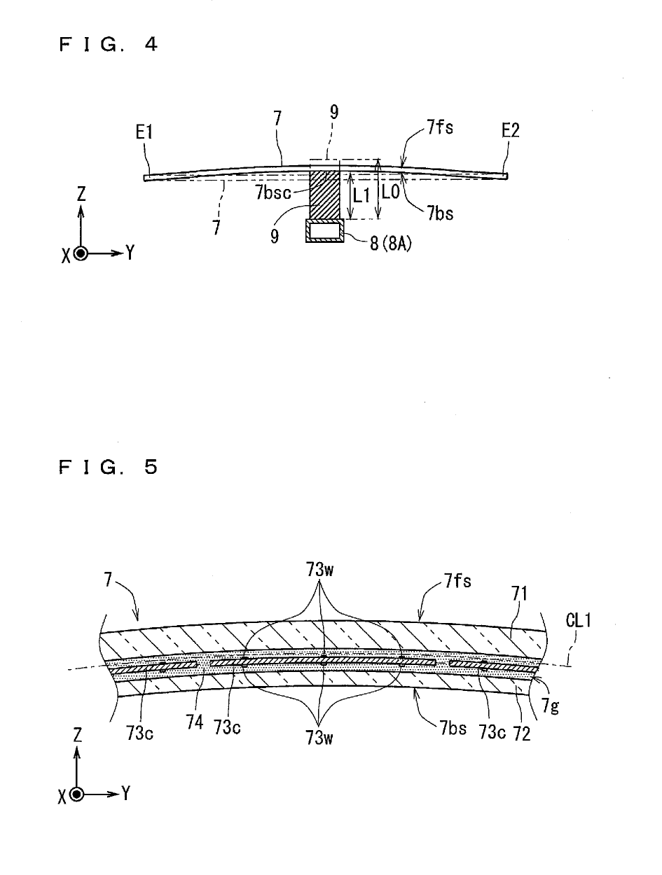

Here, as shown in FIG. 4, for example, the elastic member 9 is compressed by the pressing by the back surface 7bs of the solar cell module 7. Specifically, the elastic member 9 is assumed to have a natural length L0 in the +Z direction when no load is applied from any direction. On the other hand, the elastic member 9 has a length (also referred to as a compression length) L1 shorter than the natural length L0 in the +Z direction by elastic deformation when the elastic member 9 is pressed in the −Z direction by the back surface 7bs. At this time, the solar cell module 7 is pushed on the back surface 7bs by the elastic member 9 in response to the elastic force of the elastic body. As a result, the solar cell module 7 has the front surface Ifs convexly curved by the elastic member 9.

If such the configuration is adopted, for example, the solar cell module 7 can be easily curved such that the front surface Ifs is convexly shaped by pushing the back surface 7bs by the elastic force of the elastic body. Here, the arrangement of the elastic member 9 is easy if, for example, the configuration where the elastic member 9 is positioned in a state of pushing a central region 7bsc of the back surface 7bs by the elastic force of the elastic body is adopted. This can easily achieve the solar cell module 7 where the front surface Ifs is convexly curved by the back surface 7bs being pushed by the elastic force of the elastic body, for example. Here, the central region 7bsc of the back surface 7bs can be defined as, for example, a region including an intersection (also referred to as a center point) of diagonals of the back surface 7bs.

In the examples of FIGS. 2 to 5, the solar cell module 7 has the front surface Ifs convexly curved along the first direction (−Y direction) and the second direction (+Y direction).

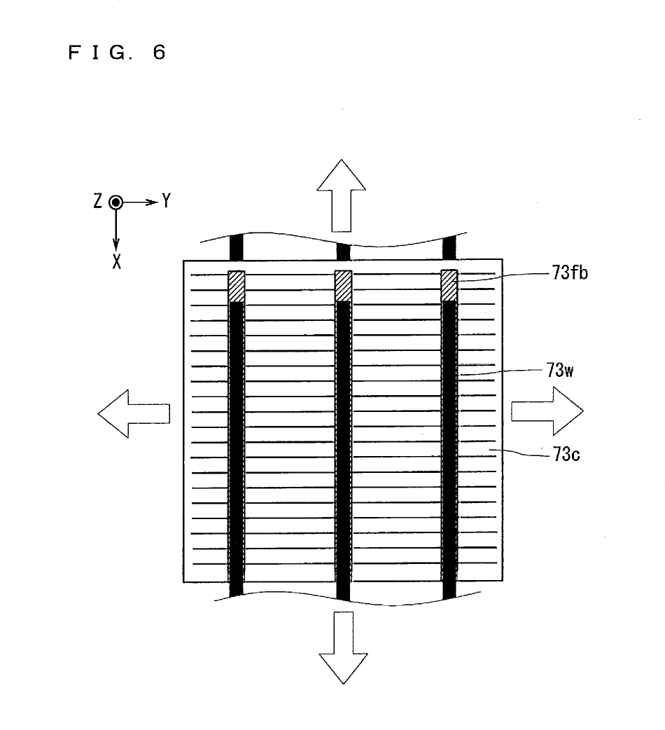

By the way, for example, if a crystalline silicon substrate is used as a substrate of the solar cell 73c, the crystalline silicon substrate has a higher strength against compressive force than that against tensile force. Here, for example, in a crystalline silicon substrate, a crack in a form of open can be generated by tension. Also, for example, in a crystalline silicon substrate, a crack in a form of buckling can be generated by compression. On the other hand, in the solar cell module 7, the wire 73w plays a role like a fiber of a fiber-reinforced composite material. As a result, the solar cell module 7 has high strength against the tensile force in the direction along the longitudinal direction of the wire 73w corresponding to the vertical direction in FIG. 6. Therefore, the solar cell 73c is easily broken if, for example, a tensile stress is applied to the solar cell 73c in the direction (1Y direction) corresponding to the right and left direction of FIG. 6 orthogonal to the longitudinal direction (here, ±X direction) of the wire 73w when the solar cell module 7 is bent.

Therefore, in the example of FIG. 5, the plurality of solar cells 73c connected via the wire 73w are positioned, for example, in a region closer to the back surface 7bs than a center (here, virtual center plane) CL1 in the thickness direction (here, +Z direction) of the solar cell module 7. In this case, in the initial state where the solar cell module 7 is curved such that the front surface Ifs is convexly shaped, a compression stress is applied to the solar cell 73c in a direction (here, ±Y direction) orthogonal to the longitudinal direction of the wire 73w (here, ±X direction). Therefore, for example, when a positive pressure load is applied to the front surface Ifs of the solar cell module 7, the solar cell module 7 first deforms in the direction where the front surface Ifs becomes flat. At this time, for example, the compression stress applied to the solar cell 73c in the direction orthogonal to the longitudinal direction of the wire 73w is released. Thereafter, for example, when the solar cell module 7 starts to deform in the direction where the front surface Ifs is concavely shaped, a tensile stress starts to be applied to the solar cell 73c in the direction orthogonal to the longitudinal direction of the wire 73w. This causes the tensile stress applied to the solar cell 73c to be less likely to increase in a direction (here, ±Y direction) orthogonal to the longitudinal direction (here, ±X direction) of the wire 73w, for example, even if the solar cell module 7 is curved such that the front surface Ifs is concavely shaped by the load of accumulated snow or the like. Accordingly, for example, the solar cell 73c becomes less likely to be broken, and the long-term reliability of the solar cell device 100 can be improved.

The elastic member 9 may be configured of an elastic body in whole or in part as long as the elastic member 9 elastically deforms expandably and contractibly in the normal direction of the back surface 7bs of the solar cell module 7, for example. However, for example, if the elastic body is present in the elastic member 9 at a position facing the back surface 7bs of the solar cell module 7, concentration of stress is less likely to occur in the solar cell module 7 when, for example, the elastic member 9 pushes the back surface 7bs of the solar cell module 7. Accordingly, it is possible to improve the long-term reliability of the solar cell device 100. More specifically, for example, if the second protector 72 of the solar cell module 7 is sheet-like configured of polyethylene terephthalate (PET) or the like, the second protector 72 may have an irregularity along the surface of the solar cell 73c and the wire 73w. In this case, for example, the elastic body present at a position facing the back surface 7bs of the elastic member 9 can deform corresponding to the irregularity of the back surface 7bs of the solar cell module 7. This causes concentration of stress to be less likely to occur in the solar cell module 7, for example, when the elastic member 9 pushes the back surface 7bs of the solar cell module 7. As a result, in the solar cell module 7, the solar cell 73c is less likely to be broken. As a material of the elastic body constituting the elastic member 9, for example, an elastomer is adopted. Here, for example, No. 1302 of Japanese Industrial Standard (JIS) K6200-2008 (corresponding to ISO 1382:2002) defines elastomer as a “polymer material that deforms with a weak force and, after removing the force, rapidly returns to approximately its original shape and size”. Specific examples of elastomer include natural rubber, synthetic natural rubber, ethylene propylene rubber, ethylene propylene diene rubber (EPDM), chloroprene rubber, silicone rubber, and fluororubber. Also, as a material of the elastic body constituting the elastic member 9, for example, foamed plastic having rubber elasticity, which is a kind of elastomer, may be adopted. Here, for example, No. 117 of Japanese Industrial Standard (JIS) K6900-1994 (corresponding to ISO 472:1988) defines foamed plastic as “plastic whose density is reduced by the presence of a multitude of continuous or discontinuous small cavities dispersed throughout the whole mass”. Specific examples of foamed plastic include those obtained by foaming urethane, silicone, natural rubber, nitrile rubber, ethylene propylene rubber, ethylene propylene diene rubber, or chloroprene rubber. Also, as a material of the elastic body constituting the elastic member 9, for example, soft plastic, which is a type of elastomer, may be adopted. Here, for example, No. 561 of Japanese Industrial Standard (JIS) K6900-1994 (corresponds to ISO 472:1988) defines soft plastic as “plastic whose elastic modulus in bending test under specified conditions, or when it is not applicable, tension test is not more than 70 MPa”.

### 1-2. Summary of First Embodiment

In the solar cell device 100 according to the first embodiment, for example, each of the solar cell modules 7 has the front surface Ifs convexly curved, and the elastic member 9 including the elastic body is in contact with the back surface 7bs. For this reason, water is less likely to gather on the front surface 7fs, for example, if the solar cell module 7 is positioned with the convex front surface Ifs facing upward and the concave back surface 7bs facing downward. In this case, for example, even if the solar cell module 7 is curved due to a load of accumulated snow or the like such that the front surface Ifs is concavely shaped, when the load on the front surface Ifs is released, the elastic member 9 causes the elastic force of the elastic body to push the back surface 7bs. As a result, for example, the front surface Ifs of the solar cell module 7 can return to a convex condition. In this manner, rainwater becomes less likely to gather on the front surface Ifs of the solar cell module 7. This makes it less likely to cause the problem that the translucency on the front surface Ifs side of the solar cell module 7 decreases due to dirt generated by the evaporation of water gathered on the front surface 7fs, for example. With such configuration, the front surface Ifs is less likely to be concavely shaped and the translucency on the front surface Ifs side is less likely to decrease for example, even if the thicknesses of the first protector 71 and the second protector 72 are thinned in order to reduce the weight of the solar cell module 7. Accordingly, it is possible to reduce the weight and improve the long-term reliability of the solar cell device 100.

### 2. Other Embodiments

The present disclosure is not limited to the above-described first embodiment, and various modifications and improvements are possible in a range without departing from the scope of the present disclosure.

### 2-1. Second Embodiment

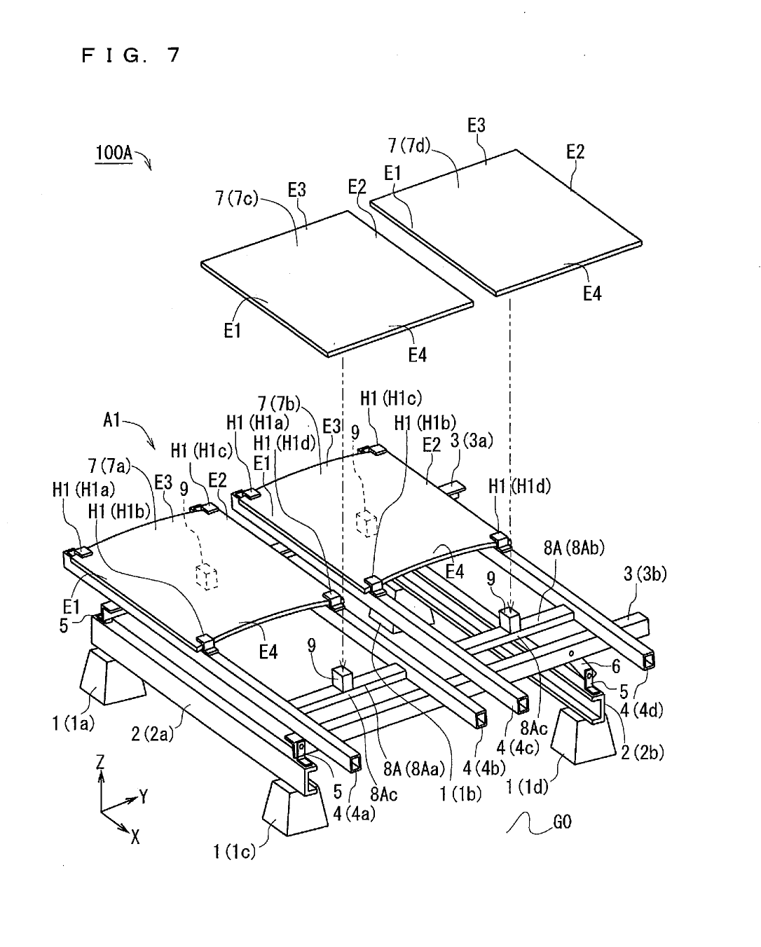

In the first embodiment, for example, as shown in FIG. 7, a solar cell device 100A including an auxiliary member 8A (also referred to as a first auxiliary member 8Aa) instead of the first auxiliary member 8a is adopted. The first auxiliary member 8Aa is positioned in a state of bridging between the first supporting member 4a as the first member of the first set and the second supporting member 4b as the second member of the first set, and is positioned in a state of facing the back surface 7bs. In this case, for example, as shown in FIG. 7, an auxiliary member 8A (also referred to as a second auxiliary member 8Ab) may be adopted instead of the second auxiliary member 8b. The second auxiliary member 8Ab is in a state of bridging between the third supporting member 4c as the first member of the second set and the fourth supporting member 4d as the second member of the second set, and is positioned in a state of facing the back surface 7bs. Here, for example, the elastic member 9 includes a part positioned between the auxiliary member 8A and the back surface 7bs. If such configuration is adopted, for example, the elastic member 9 can be easily arranged by arranging the elastic member 9 between the back surface 7bs of the solar cell module 7 and the auxiliary member 8A. This can easily achieve the solar cell module 7 where the front surface Ifs is convexly curved, for example.

Here, the elastic member 9 is positioned between the back surface 7bs of the first solar cell module 7a and the first auxiliary member 8Aa, which is positioned in a state of facing the back surface 7bs of the first solar cell module 7a. The elastic member 9 is positioned between the back surface 7bs of the second solar cell module 7b and the second auxiliary member 8Ab, which is positioned in a state of facing the back surface 7bs of the second solar cell module 7b. The elastic member 9 is positioned between the back surface 7bs of the third solar cell module 7c and the first auxiliary member 8Aa, which is positioned in a state of facing the back surface 7bs of the third solar cell module 7c. The elastic member 9 is positioned between the back surface 7bs of the fourth solar cell module 7d and the second auxiliary member 8Ab, which is positioned in a state of facing the back surface 7bs of the fourth solar cell module 7d.

Here, for example, the first auxiliary member 8Aa may be positioned in a state of linearly bridging between the first supporting member 4a as the first member of the first set and the second supporting member 4b as the second member of the first set. Also, for example, the second auxiliary member 8Ab may be positioned in a state of linearly bridging between the third supporting member 4c as the first member of the second set and the fourth supporting member 4d as the second member of the second set. In this case, for example, it is possible to easily manufacture the auxiliary members 8A including the first auxiliary member 8Aa and the second auxiliary member 8Ab by extrusion molding of aluminum or the like without performing processing such as roll forming. For example, the adoption of the auxiliary member 8A having a simple structure can reduce the weight and size of the auxiliary member 8A, the usage amount of the material constituting the auxiliary member 8A, the energy required for manufacturing the auxiliary member 8A and the like. In the example of FIG. 7, a rod-like member having the configuration of a square cylinder is adopted as the auxiliary member 8A.

Also, for example, the elastic member 9 may include a part positioned on a central region 8Ac in the longitudinal direction (here, ±Y direction) of the auxiliary member 8A. In this case, for example, the auxiliary member 8A, in which the elastic member 9 is positioned near the center in the longitudinal direction, is attached to the first supporting member 4a as the first member of the first set and the second supporting member 4b as the second member of the first set. Alternatively, the auxiliary member 8A is attached to the third supporting member 4c as the first member of the second set and the fourth supporting member 4d as the second member of the second set. This allows the solar cell module 7 to be easily curved so that the front surface Ifs is convexly shaped. Here, for example, when the auxiliary member 8A is virtually divided equally into five sections in the longitudinal direction of the auxiliary member 8A, a region positioned at the third section at the center may be defined as the central region 8Ac. In the example of FIG. 7, the elastic member 9 is positioned on the central region 8Ac in the longitudinal direction (±Y direction) of the auxiliary member 8A.

### 2-2. Third Embodiment

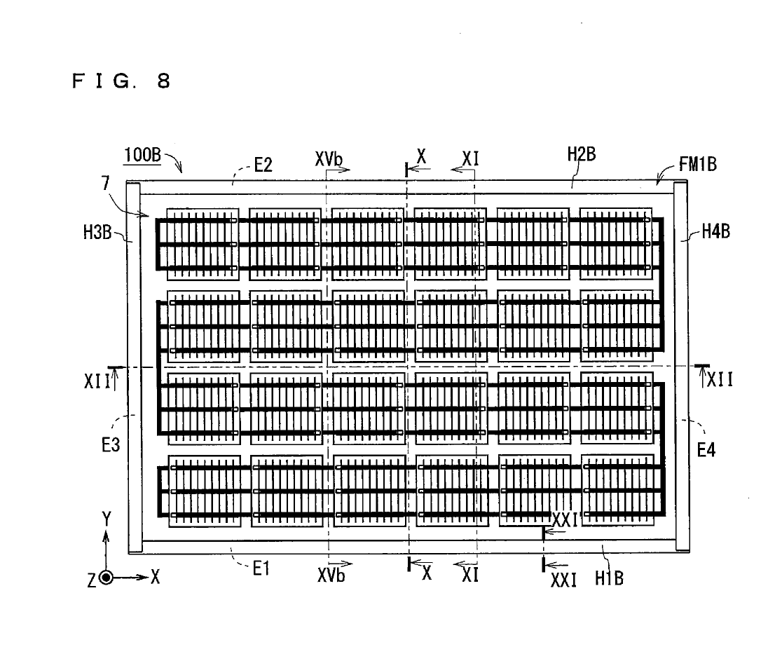

In each of the above embodiments, for example, a solar cell device 100B as shown in FIGS. 8 to 13 may be adopted. For example, the solar cell device 100B, in which a frame FM1B is positioned along the outer perimeter of the solar cell module 7 and an elastic member 9B is positioned on an auxiliary member 8B positioned in a state of bridging to the frame FM1B, may be adopted.

The solar cell device 100B according to the third embodiment will be described with reference to FIGS. 8 to 13. As shown in FIGS. 8 to 12, the solar cell device 100B includes, for example, the one solar cell module 7, the frame FM1B, the auxiliary member 8B, and the elastic member 9B.

The frame FM1B includes, for example, a first member H1B, a second member H2B, a third member H3B, and a fourth member H4B. For example, the first member H1B, the third member H3B, the second member H2B, and the fourth member H4B are annularly coupled in the order of this description, thus being in a state of constituting the annular frame FM1B that surrounds the entire perimeter of the outer perimeter of the solar cell module 7.

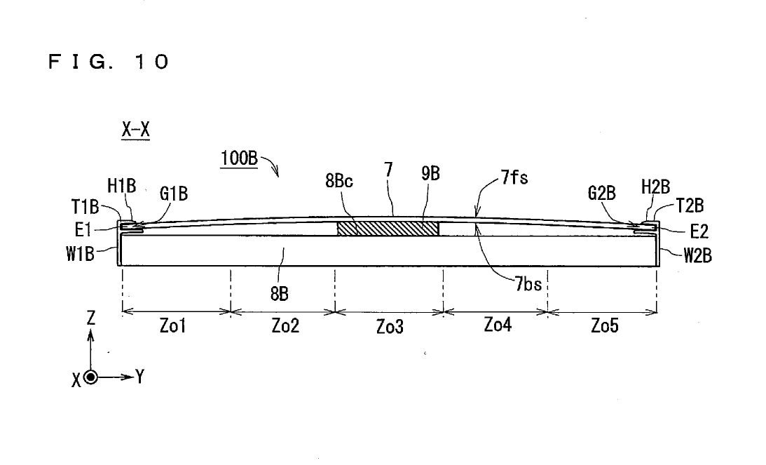

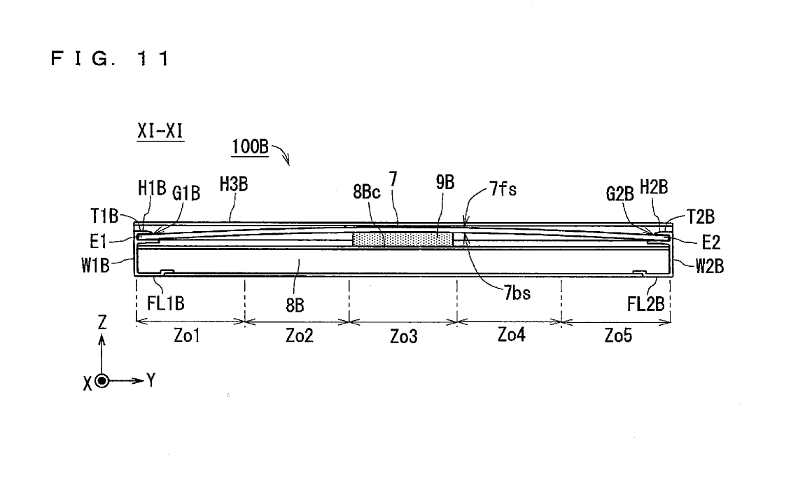

The first member H1B is positioned in a state of supporting the first outer edge portion E1 positioned along one side of the solar cell module 7 present at the end facing in the first direction (−Y direction), for example. In the examples of FIGS. 10 and 11, the first member H1B includes a first groove portion T1B. The first groove portion T1B has a first recess G1B that is recessed in the first direction (−Y direction). The first recess G1B is positioned in a state of extending along the fourth direction (−X direction). The first outer edge portion E1 of the solar cell module 7 is positioned in a state of fitting in the first recess G1B of the first groove portion T1B. This allows the first member H1B to hold the first outer edge portion E1.

The second member H2B is positioned in a state of supporting, for example, the second outer edge portion E2 positioned along one side of the solar cell module 7 present at the end facing in the second direction (+Y direction). In the examples of FIGS. 10 and 11, the second member H2B includes a second groove portion T2B. The second groove portion T2B has a second recess G2B that is recessed in the second direction (+Y direction). The second recess G2B is positioned in a state of extending along the fourth direction (−X direction). The second outer edge portion E2 of the solar cell module 7 is positioned in a state of fitting in the second recess G2B of the second groove portion T2B. This allows the second member H2B to hold the second outer edge portion E2.

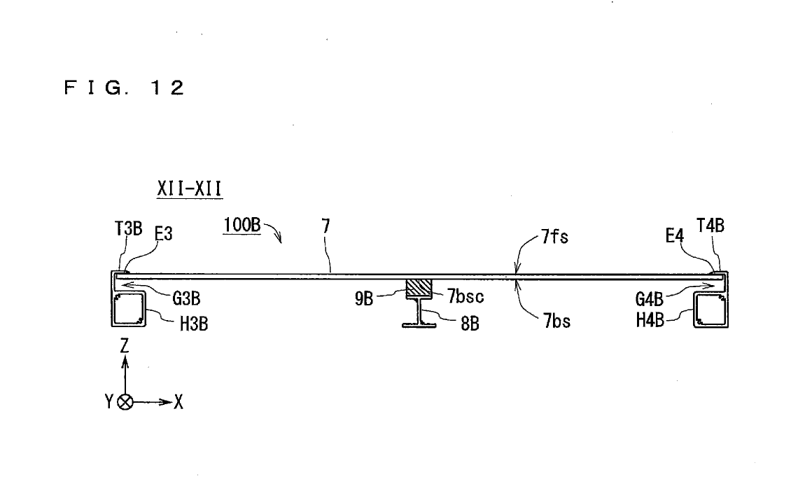

The third member H3B is positioned in a state of supporting, for example, the third outer edge portion E3 positioned along one side of the solar cell module 7 present at the end facing in the fourth direction (−X direction). In the example of FIG. 12, the third member H3B includes a third groove portion T3B. The third groove portion T3B has a third recess G3B that is recessed in the fourth direction (−X direction). The third recess G3B is positioned in a state of extending along the first direction (−Y direction). The third outer edge portion E3 of the solar cell module 7 is positioned in a state of fitting in the third recess G3B of the third groove portion T3B. This allows the third member H3B to hold the third outer edge portion E3.

The fourth member H4B is positioned in a state of supporting, for example, the fourth outer edge portion E4 positioned along one side of the solar cell module 7 present at the end facing in the fifth direction (+X direction). In the example of FIG. 12, the fourth member H4B includes a fourth groove portion T4B. The fourth groove portion T4B has a fourth recess G4B that is recessed in the fifth direction (+X direction). The fourth recess G4B is positioned in a state of extending along the first direction (−Y direction). The fourth outer edge portion E4 of the solar cell module 7 is positioned in a state of fitting in the fourth recess G4B of the fourth groove portion T4B. This allows the fourth member H4B to hold the fourth outer edge portion E4.

The auxiliary member 8B is positioned in a state of bridging, for example, between the first member H1B and the second member H2B. In addition, the auxiliary member 8B faces the back surface of the solar cell module 7. Here, the auxiliary member 8B may be in a state of linearly bridging between the first member H1B and the second member H2B. In this case, it is possible to easily manufacture the auxiliary member 8B, for example, by extrusion molding of aluminum or the like. For example, the adoption of the auxiliary member 8B having a simple structure can reduce the weight and size of the auxiliary member 8B, the usage amount of the material constituting the auxiliary member 8B, and the energy required for manufacturing the auxiliary member 8B. In the examples of FIGS. 8 to 12, a member having an H-shaped configuration in cross-section perpendicular to the longitudinal direction of the auxiliary member 8B is adopted as the auxiliary member 8B.

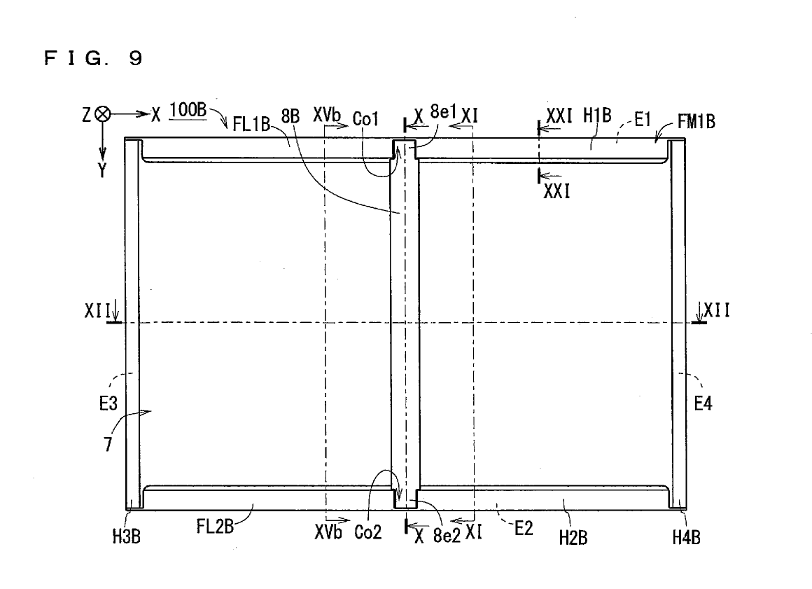

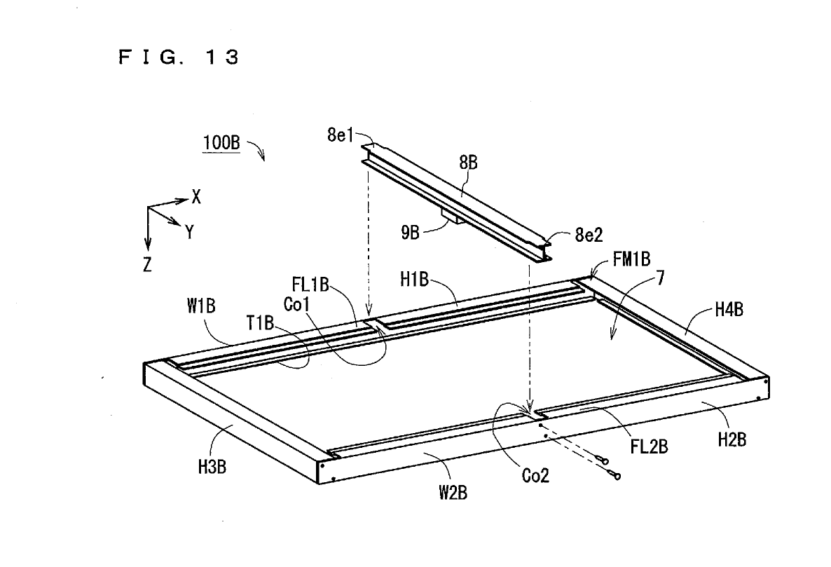

Here, as shown in FIGS. 9 to 11 and 13, the first member H1B includes, for example, the first groove portion T1B, a first wall portion W1B, and a first protrusion portion FL1B. The first wall portion W1B is positioned in a state of extending from the first groove portion T1B, for example, along the third direction (−Z direction) from the front surface Ifs toward the back surface 7bs. The first protrusion portion FL1B is positioned in a state of protruding in the second direction (+Y direction) from the part of the first wall portion W1B positioned away from the first groove portion T1B in the third direction (−Z direction), for example. The first protrusion portion FL1B further includes a first fitted part Co1 at an end part close to the second member H2B in the second direction (+Y direction). The first fitted part Co1 has openings in, for example, a part facing in the second direction (+Y direction), a part facing in the third direction (−Z direction), and a part facing in the +Z direction as a sixth direction opposite the third direction. In the examples of FIGS. 9 and 13, the first protrusion portion FL1B is a flange-like part protruding towards the second direction (+Y direction) from the end of the first wall portion W1B facing in the third direction (−Z direction). The first fitted part Co1 is a notched part in which the edge facing in the second direction (+Y direction) is positioned in a state of being recessed towards the first direction (−Y direction) in the vicinity of the center of the first protrusion portion FL1B in the fourth direction (−X direction).

As shown in FIGS. 9 to 11 and 13, the second member H2B has, for example, a plane-symmetrical relationship based on the XZ plane with respect to the first member H1B. Specifically, the second member H2B includes, for example, the second groove portion T2B, a second wall portion W2B, and a second protrusion portion FL2B. The second wall portion W2B is positioned in a state of extending from the second groove portion T2B along the third direction (−Z direction), for example. The second protrusion portion FL2B is positioned in a state of protruding in the first direction (−Y direction) from the part of the second wall portion W2B positioned away from the second groove portion T2B in the third direction (−Z direction), for example. The second protrusion portion FL2B further includes a second fitted part Co2 at an end part close to the first member H1B in the first direction (−Y direction). The second fitted part Co2 has openings in, for example, a part facing in the first direction (−Y direction), a part facing in the third direction (−Z direction), and a part facing in the sixth direction (+Z direction). In the examples of FIGS. 9 and 13, the second protrusion portion FL2B is a flange-like part protruding towards the first direction (−Y direction) from the end of the second wall portion W2B facing in the third direction (−Z direction). The second fitted part Co2 is a notched part in which the edge facing in the first direction (−Y direction) is positioned in a state of being recessed towards the second direction (+Y direction) in the vicinity of the center of the second protrusion portion FL2B in the fourth direction (−X direction).

In addition, the auxiliary member 8B includes a first fitting part 8e1 positioned at an end part close to the first member H1B in the first direction (−Y direction), and a second fitting part 8e2 positioned at an end part close to the second member H2B in the second direction (+Y direction). Here, as shown in FIGS. 9 and 13, the first fitting part 8e1 is positioned in a state of being fixed to the first member H1B while being fitted into the first fitted part Co1. The second fitting part 8e2 is positioned in a state of being fixed to the second member H2B while being fitted into the second fitted part Co2. Here, as shown in FIG. 13, the first fitting part 8e1 is positioned in a state of being fixed to the first member H1B with a screw penetrating the first member H1B, while being fitted into the first fitted part Co1, for example. The second fitting part 8e2 is positioned in a state of being fixed to the second member H2B with a screw penetrating the second member H2B, while being fitted into the second fitted part Co2, for example. According to such configuration, for example, the auxiliary member 8B to which the elastic member 9B is attached can be easily fixed to the first member H1B and the second member H2B. This allows compression of the elastic member 9B to be easily realized between the back surface 7bs of the solar cell module 7 and the auxiliary member 8B, for example.

The elastic member 9B includes at least a part positioned between the auxiliary member 8B and the back surface 7bs of the solar cell module 7. In the example of FIGS. 10 to 12, the elastic member 9B is positioned between the back surface 7bs of the solar cell module 7 and the auxiliary member 8B. The elastic member 9B includes an elastic body and is in contact with the back surface 7bs. Here, for example, even if the solar cell module 7 is curved due to a load of accumulated snow or the like such that the front surface Ifs is concavely shaped, when the load on the front surface Ifs is released, the elastic member 9B causes the elastic force of the elastic body to push the back surface 7bs. As a result, for example, the front surface Ifs of the solar cell module 7 can return to a convex condition. This makes it less likely to cause the problem that the translucency on the front surface Ifs side of the solar cell module 7 decreases due to dirt generated by the evaporation of water gathered on the front surface 7fs, for example. Accordingly, it is possible to reduce the weight and improve the long-term reliability of the solar cell device 100B.

Here, for example, the elastic member 9B is positioned in a state of being compressed by the pressing by the back surface 7bs of the solar cell module 7, as in the elastic member 9 according to each of the above embodiments. At this time, the solar cell module 7 is pushed on the back surface 7bs by the elastic member 9B in response to the elastic force of the elastic body. Therefore, the solar cell module 7 has the front surface 7fs convexly curved by the elastic member 9B. With such the configuration, for example, the solar cell module 7 can be easily curved such that the front surface Ifs is convexly shaped by pushing the back surface 7bs by the elastic force of the elastic body. Here, the arrangement of the elastic member 9B is easy if, for example, the configuration where the elastic member 9B is positioned in a state of pushing a central region 7bsc of the back surface 7bs by the elastic force of the elastic body is adopted. This can easily achieve the solar cell module 7 where the front surface Ifs is in a state of being convexly curved by the back surface 7bs being pushed by the elastic force of the elastic body, for example.

In the example of FIGS. 8 to 12, the solar cell module 7 has the front surface 7fs convexly curved along the first direction (−Y direction) and the second direction (+Y direction). This causes the tensile stress applied to the solar cell 73c to be less likely to increase in a direction (here, ±Y direction) orthogonal to the longitudinal direction (here, ±X direction) of the wire 73w, for example, even if the solar cell module 7 is curved such that the front surface Ifs is concavely shaped by the load of accumulated snow or the like. Accordingly, for example, the solar cell 73c becomes less likely to be broken, and the long-term reliability of the solar cell device 100B can be improved.

As the structure and material of the elastic member 9B, the structure and material of the elastic member 9 according to each of the embodiments, for example, can be adopted. Here, for example, if the elastic body is present in the elastic member 9B at a position facing the back surface 7bs of the solar cell module 7, concentration of stress is less likely to occur in the solar cell module 7 when, for example, the elastic member 9B pushes the back surface 7bs of the solar cell module 7. As a result, in the solar cell module 7, the solar cell 73c is less likely to be broken. As a material of the elastic body constituting the elastic member 9B, for example, an elastomer is adopted. Elastomers can include, for example, foamed plastic, soft plastic and the like each having rubber elasticity.

Also, for example, the elastic member 9B may have a part positioned on a central region 8Bc in the longitudinal direction (here, ±Y direction) of the auxiliary member 8B. In this case, it is possible to easily achieve the solar cell module 7 where the front surface Ifs is convexly curved by, for example, attaching the auxiliary member 8B in which the elastic member 9B is positioned near the center in the longitudinal direction to the first member H1B and the second member H2B. Here, for example, as shown in FIGS. 10 and 11, when the auxiliary member 8B is virtually divided equally into five sections Zo1, Zo2, Zo3, Zo4, and Zo5 in the longitudinal direction of the auxiliary member 8B, the region positioned at the third section Zo3 at the center may be defined as the central region 8Bc. In the examples of FIGS. 10 and 11, the elastic member 9B is positioned on the central region 8Bc in the longitudinal direction (+Y direction) of the auxiliary member 8B.

### 2-3. Fourth Embodiment

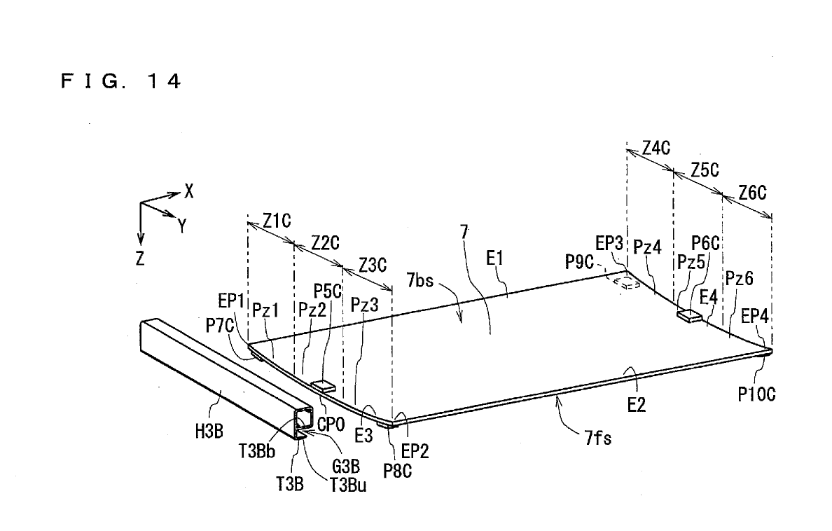

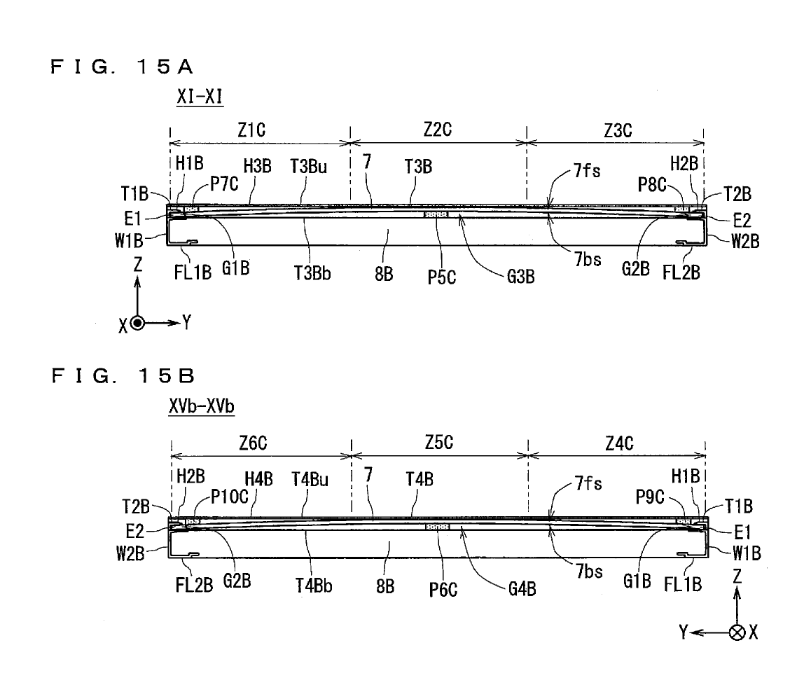

In the third embodiment, for example, as shown in FIGS. 14, 15A, and 15B, a fifth member P5C positioned substantially at the center on the back surface 7bs of the third outer edge portion E3 may be added and a sixth member P6C positioned substantially at the center on the back surface 7bs of the fourth outer edge portion E4 may be added. Here, as the fifth member P5C and the sixth member P6C, for example, thin members including an elastic body are adopted. As the material of this elastic body, for example, the same material as the material of the elastic member 9B is adopted.

Specifically, for example, as shown in FIG. 14, it is assumed that in the second direction (+Y direction), the third outer edge portion E3 is virtually divided equally into the three of a part Pz1 of a first section Z1C including a first end part EP1, a part Pz2 of a second section (also referred to as a first central section) Z2C including a central part CP0, and a part Pz3 of a third section Z3C including a second end part EP2 opposite the first end part EP1. In this case, for example, the fifth member P5C is positioned between the third member H3B and the region of the second section Z2C on the back surface 7bs of the third outer edge portion E3. In the example of FIG. 15A, in the third recess G3B of the third groove portion T3B of the third member H3B, the third outer edge portion E3 is positioned in a state of being supported by the fifth member P5C. More specifically, the third groove portion T3B includes, for example, a first upper part T3Bu facing the front surface Ifs in the third outer edge portion E3, and a first lower part T3Bb facing the back surface 7bs in the third outer edge portion E3. The fifth member P5C is positioned between the first lower part T3Bb and the region of the second section Z2C of the third outer edge portion E3 on the back surface 7bs.

Also, for example, as shown in FIG. 14, it is assumed that in the second direction (+Y direction), the fourth outer edge portion E4 is virtually divided equally into the three of a part Pz4 of a fourth section Z4C including a third end part EP3, a part Pz5 of a fifth section (also referred to as a second central section) Z5C including the central part CP0, and a part Pz6 of a sixth section Z6C including a fourth end part EP4 opposite the third end part EP3. In this case, for example, the sixth member P6C is positioned between the fourth member H4B and the region of the fifth section Z5C on the back surface 7bs of the fourth outer edge portion E4. In the example of FIG. 15B, similarly to the third outer edge portion E3, in the fourth recess G4B of the fourth groove portion T4B of the fourth member H4B, the fourth outer edge portion E4 is positioned in a state of being supported by the sixth member P6C. More specifically, the fourth groove portion T4B includes, for example, a second upper part T4Bu facing the front surface Ifs in the fourth outer edge portion E4, and a second lower part T4Bb facing the back surface 7bs in the fourth outer edge portion E4. The sixth member P6C is positioned between the second lower part T4Bb and the region of the fifth section Z5C of the fourth outer edge portion E4 on the back surface 7bs.

In the example of FIG. 15A, the fifth member P5C is in a state of being sandwiched by the first lower part T3Bb and the back surface 7bs. In the example of FIG. 15B, the sixth member P6C is in a state of being sandwiched by the second lower part T4Bb and the back surface 7bs. The fifth member P5C and the sixth member P6C may elastically deform while being compressed by the pressing by the back surface 7bs, or may not be pressed by the back surface 7bs. Here, when the fifth member P5C and the sixth member P6C are pressed by the back surface 7bs, the back surface 7bs is pushed in the sixth direction (+Z direction) by the elastic force of the fifth member P5C and the sixth member P6C.

Thus, for example, assuming that the back surface 7bs of the solar cell module 7 is supported by the fifth member P5C and the sixth member P6C in addition to the elastic member 9B, it is possible to easily curve the solar cell module 7 along the first direction (−Y direction). At this time, it is possible to disperse stress applied to the back surface 7bs of the solar cell module 7 to curve the solar cell module 7, for example. As a result, the solar cell module 7 becomes less likely to be damaged, and the long-term reliability of the solar cell device 100B can be improved.

Also, for example, as shown in FIGS. 14, 15A, and 15B, a seventh member P7C and an eighth member P8C positioned near both ends on the front surface Ifs of the third outer edge portion E3 may be added and a ninth member P9C and a tenth member P10C positioned near both ends on the front surface Ifs of the fourth outer edge portion E4 may be added. Here, as the seventh member P7C, the eighth member P8C, the ninth member P9C, and the tenth member P10C, for example, thin members including an elastic body are adopted. As the material of this elastic body, for example, the same material as the material of the elastic member 9B is adopted.

Specifically, as shown in FIGS. 14 and 15A, for example, the seventh member P7C is positioned between the first upper part T3Bu of the third member H3B and the region of the first section Z1C on the front surface Ifs of the third outer edge portion E3. For example, the eighth member P8C is positioned between the first upper part T3Bu of the third member H3B and the region of the third section Z3C on the front surface Ifs of the third outer edge portion E3. This allows the third outer edge portion E3 to be easily curved along the first direction (−Y direction) by the fifth member P5C, the seventh member P7C, and the eighth member P8C in the third recess G3B of the third groove portion T3B of the third member H3B, for example. Also, as shown in FIGS. 14 and 15B, for example, the ninth member P9C is positioned between the second upper part T4Bu of the fourth member H4B and the region of the fourth section Z4C on the front surface Ifs of the fourth outer edge portion E4. For example, the tenth member P10C is positioned between the second upper part T4Bu of the fourth member H4B and the region of the sixth section Z6C on the front surface Ifs of the fourth outer edge portion E4. Similar to the third outer edge portion E3, this allows the fourth outer edge portion E4 to be easily curved along the first direction (−Y direction) by the sixth member P6C, the ninth member P9C, and the tenth member P10C in the fourth recess G4B of the fourth groove portion T4B of the fourth member H4B, for example. Also, here, for example, it is possible to disperse stress applied to the solar cell module 7 to curve the solar cell module 7, for example. As a result, the solar cell module 7 becomes less likely to be damaged, and the long-term reliability of the solar cell device 100B can be improved.

In the example of FIG. 15A, the seventh member P7C and the eighth member P8C are positioned in a state of being sandwiched by the front surface Ifs of the third outer edge portion E3 and the first upper part T3Bu. The seventh member P7C and the eighth member P8C may elastically deform while being compressed by the front surface 7fs of the third outer edge portion E3 and the first upper part T3Bu, or may not elastically deform without being compressed by the front surface Ifs of the third outer edge portion E3 and the first upper part T3Bu. Here, when the seventh member P7C and the eighth member P8C are compressed, the front surface Ifs of the third outer edge portion E3 is pushed down in the third direction (−Z direction) by the elastic force of the seventh member P7C and the eighth member P8C.

In the example of FIG. 15B, the ninth member P9C and the tenth member P10C are positioned in a state of being sandwiched by the front surface Ifs of the fourth outer edge portion E4 and the second upper part T4Bu. The ninth member P9C and the tenth member P10C may elastically deform while being compressed by the front surface Ifs of the fourth outer edge portion E4 and the second upper part T4Bu, or may not elastically deform without being compressed by the front surface Ifs of the fourth outer edge portion E4 and the second upper part T4Bu. Here, when the ninth member P9C and the tenth member P10C are compressed, the front surface Ifs of the fourth outer edge portion E3 is pushed down in the third direction (−Z direction) by the elastic force of the ninth member P9C and the tenth member P10C.

### 2-4. Fifth Embodiment

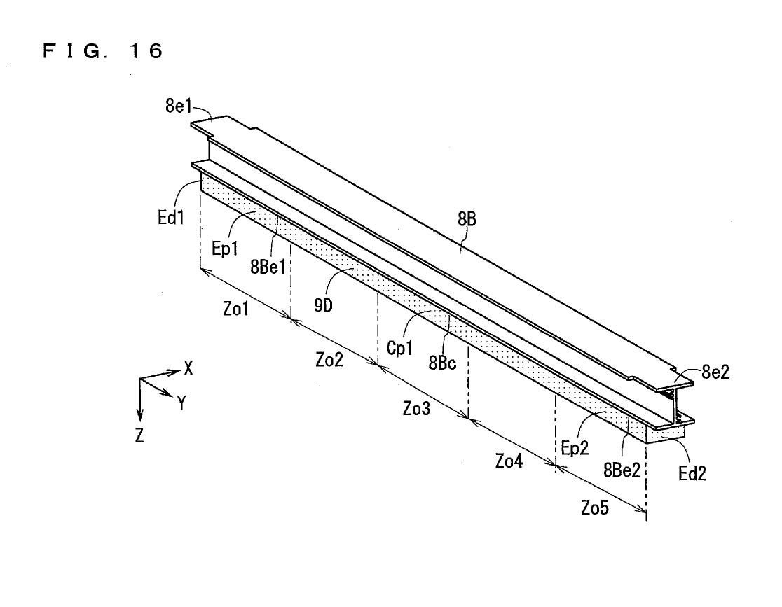

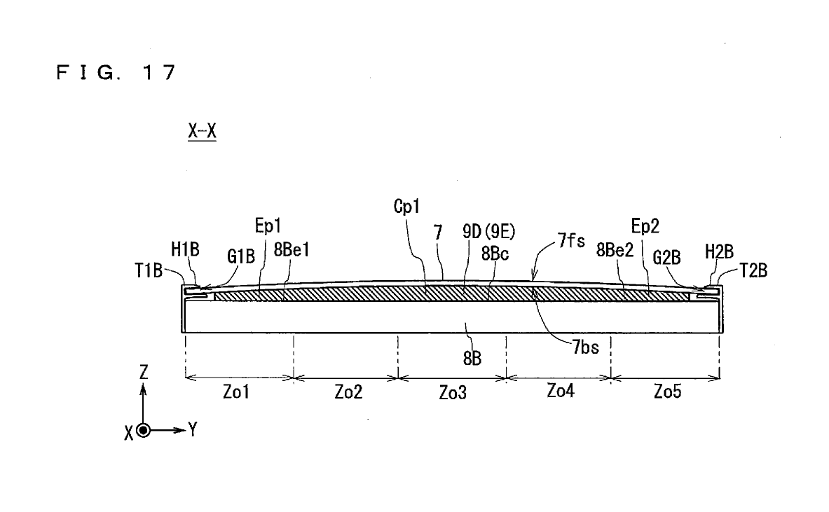

In the third embodiment and the fourth embodiment, for example, as shown in FIGS. 16 and 17, the elastic member 9B may be exchanged to an elastic member 9D including a part positioned along the longitudinal direction of the auxiliary member 8B between the back surface 7bs and the auxiliary member 8B. In this case, the elastic member 9D includes, for example, a first end part Ep1, a central part Cp1, and a second end part Ep2 in the longitudinal direction (±Y direction) of the auxiliary member 8B. Here, for example, the central part Cp1 is positioned on the central region 8Bc. The first end part Ep1 is positioned on a region (also referred to as a first end region) 8Be1 closer to one edge part (also referred to as a first edge part) Ed1 than the central region 8Bc in the longitudinal direction (±Y direction) of the auxiliary member 8B. The second end part Ep2 is positioned on a region (also referred to as a second end part region) 8Be2 closer to the other edge part (also referred to as a second edge part) Ed2 opposite the first edge part Ed1 than the central region 8Bc in the longitudinal direction (+Y direction) of the auxiliary member 8B.

In the examples of FIGS. 16 and 17, similarly to FIGS. 10 and 11, when the auxiliary member 8B is virtually divided equally into five sections Zo1, Zo2, Zo3, Zo4, and Zo5 in the +Y direction as the longitudinal direction of the auxiliary member 8B, the region positioned at the third section Zo3 at the center may be defined as the central region 8Bc. Further, here, the region positioned in the part of the first section Zo1 is defined as the first end region 8Be1. The region positioned in the fifth section Zo5 is defined as the second end region 8Be2.

Here, for example, the elastic member 9D is in a state of being compressed by the pressing by the back surface 7bs. At this time, for example, the elastic member 9D has a compression amount by the back surface 7bs in the first end part Ep1 and the second end part Ep2 larger than the compression amount by the back surface 7bs in the central part Cp1. In such a case, for example, as shown in FIG. 16, it is possible to adopt the elastic member 9D having a uniform thickness (also referred to as a natural thickness) when not pressed by the back surface 7bs. This can improve productivity of the elastic member 9D.

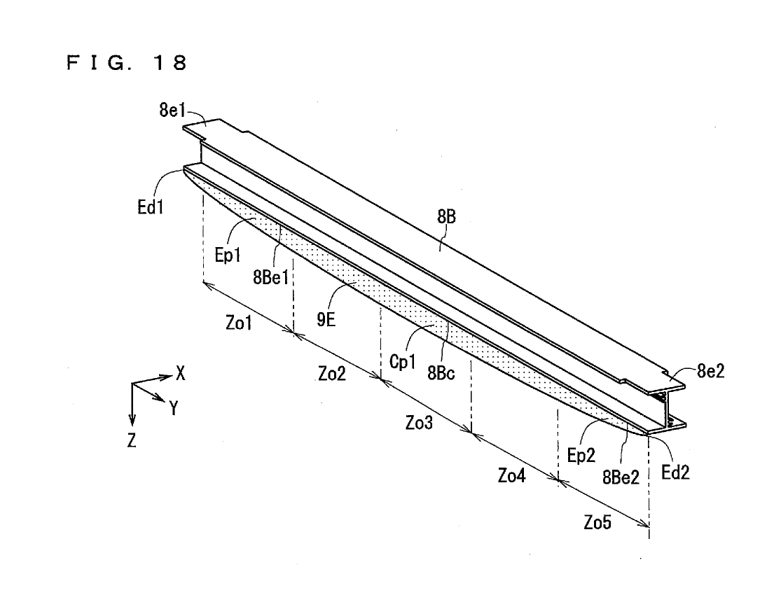

Here, for example, as shown in FIGS. 17 and 18, instead of the elastic member 9D, an elastic member 9E having a natural thickness smaller at the first end part Ep1 and the second end part Ep2 than at the central part Cp1 may be adopted. In the example of FIG. 18, the natural thickness of the elastic member 9E is continuously reduced as separated from the central part Cp1 in the longitudinal direction (±Y direction) of the elastic member 9E. In such a case, for example, when compressed by the pressing by the back surface 7bs, the elastic member 9E can have a uniform compression ratio by the back surface 7bs of the elastic member 9E from the first edge part Ed1 to the second edge part Ed2 via the central part Cp1. In this case, for example, in a part of the elastic member 9E pressed by the back surface 7bs of the solar cell module 7, it is possible to uniformly disperse the positive pressure load due to accumulated snow or the like. As a result, the solar cell module 7 becomes less likely to be damaged.

### 2-5. Sixth Embodiment

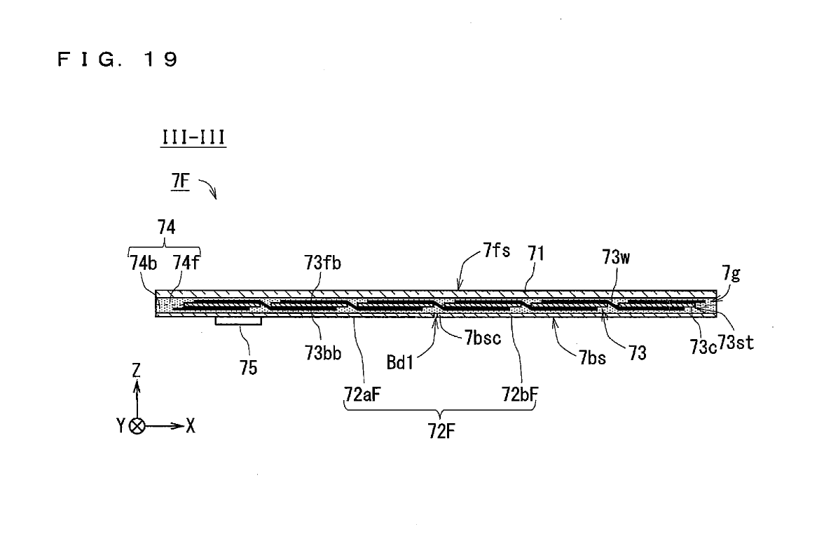

In each of the above embodiments, for example, as shown in FIG. 19, instead of the solar cell module 7, a solar cell module 7F, in which the second protector 72 of the solar cell module 7 is changed to a second protector 72F formed of a combination of a plurality of chemically strengthened glasses, may be adopted. In the example of FIG. 19, the second protector 72F includes a first plate 72aF and a second plate 72bF positioned in a state of being adjacently arrayed in the fourth direction (−X direction) along the back surface 7bs. Each of the first plate 72aF and the second plate 72bF is a plate-like member made of chemically strengthened glass. The first plate 72aF and the second plate 72bF have the same rectangular front and back surfaces. The second protector 72F is configured such that the first plate 72aF and the second plate 72bF are in close proximity to each other at an adjacent part Bd1. The adjacent part Bd1 is a part where the first plate 72aF and the second plate 72bF are adjacent to each other.

Here, for example, if the elastic member 9, 9B, 9D, or 9E is present with the central region 7bsc of the back surface 7bs being pushed by the elastic force of the elastic body, the elastic member 9, 9B, 9D, or 9E is in contact with the adjacent part Bd1. At this time, the solar cell module 7F has the front surface Ifs convexly curved along the first direction (−Y direction) and the second direction (+Y direction).

By the way, for example, it is difficult to manufacture a chemically strengthened thin glass having large front and back areas because the temperature control to uniform the temperature of the chemical solution in contact over the entire front and back of the glass is difficult in a chemical bath in which sodium ions and potassium ions in the glass are replaced.

Therefore, as described above, the productivity of the second protector 72F can be enhanced by, for example, configuring the second protector 72F of the solar cell module 7F with a combination of a plurality of glass plates made of chemically strengthened glass. Also, for example, if the second protector 72F is divided into a plurality of plates in the direction orthogonal to the direction in which the solar cell module 7F is curved, not only the first protector 71 but also the second protector 72F can support the stress that causes the solar cell module 7F to be curved. This reduces the reduction in strength of the solar cell module 7F even if, for example, the divided second protector 72F is adopted.

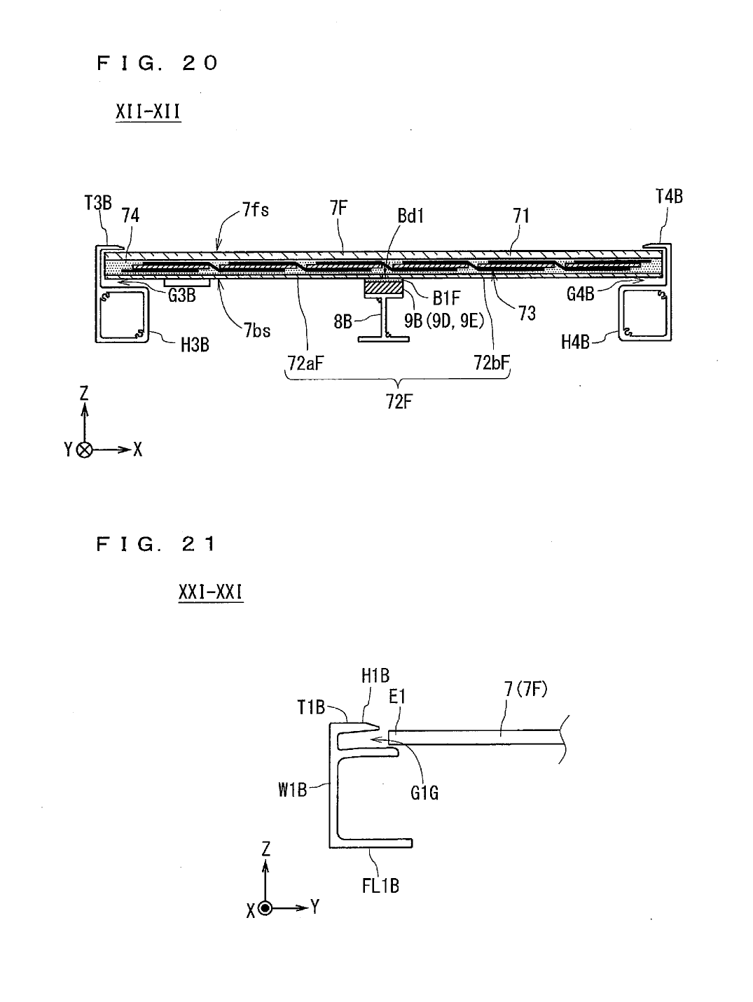

Further, here, as shown in FIG. 20, for example, a configuration including an adhesion B1F positioned in a state of causing the elastic member 9, 9B, 9D, or 9E to adhere to the first plate 72aF and the second plate 72bF may be adopted. In this case, the adhesion B1F covers the adjacent part Bd1. This reduces intrusion of moisture to the inside of the solar cell module 7F (here, the gap 7g) from the external space of the solar cell module 7F through the gap between the first plate 72aF and the second plate 72bF, for example.

In the example of FIG. 20, the elastic member 9, 9B, 9D, or 9E is in proximity to the adjacent part Bd1 across the adhesion B1F. And, for example, the greater the length of the elastic member 9, 9B, 9D, or 9E in the first direction (−Y direction) is, the greater the ratio of the part of the entire adjacent part Bd1 being covered with the adhesion B1F becomes. In this case, for example, the adhesion B1F covers the adjacent part Bd1 along the adjacent part Bd1. This reduces intrusion of moisture to the inside of the solar cell module 7F from the external space of the solar cell module 7F, for example.

### 2-6. Seventh Embodiment

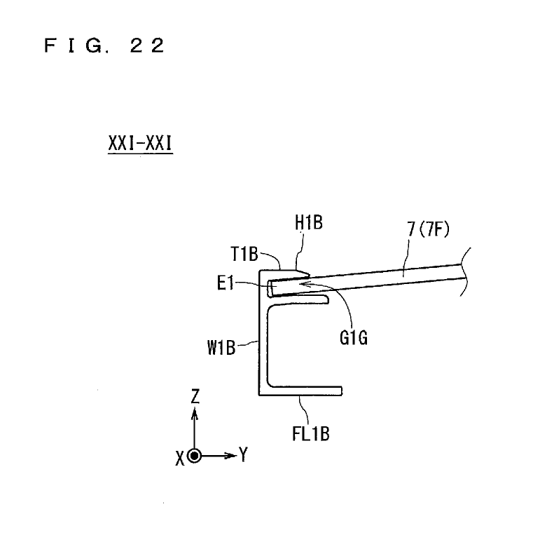

In the third embodiment to the sixth embodiment, for example, as shown in FIG. 21, the first recess G1B of the first groove portion T1B of the first member H1B may be changed to a first recess G1G having the direction of recess slightly inclined in the −Z direction. For example, similarly to the first recess G1B, the second recess G2B of the second groove portion T2B of the second member H2B may also have the direction of recess slightly inclined in the −Z direction. If such configuration is adopted, for example, as shown in FIG. 22, the first outer edge portion E1 of the solar cell module 7 or 7F may be in a state of being held while being inclined by the first member H1B. Further, for example, the second outer edge portion E2 of the solar cell module 7 or 7F may be in a state of being held while being inclined by the second member H2B. At this time, for example, the solar cell module 7 or 7F may have the front surface Ifs convexly curved along the first direction (−Y direction) and the second direction (+Y direction). If such configuration is adopted, it is not necessary to curve the solar cell module 7 or 7F so that the front surface Ifs is convexly shaped by the elastic force of the elastic member 9, 9B, 9D, or 9E, for example. In this case, for example, with the solar cell module 7 or 7F being curved so that the front surface Ifs is convexly shaped, the elastic member 9, 9B, 9D, or 9E may be in contact with the back surface 7bs of the solar cell module 7 or 7F or may be in proximity to the back surface 7bs.

### 3. Others

In the first embodiment, for example, the elastic member 9 may also be positioned directly on the installation object G0. For example, if the installation object G0 is a roof of a building or the like, the elastic member 9 can be directly positioned onto the installation object G0 by adhesion using an adhesive, coupling using a metal fitting or the like.

In the third embodiment to the seventh embodiment, for example, the frame FM1B has a form in which the four linear members, i.e., the first member H1B, the second member H2B, the third member H3B, and the fourth member H4B are coupled.

However, the embodiments are not limited to this. For example, two members or three members of the first member H1B, the second member H2B, the third member H3B, and the fourth member H4B may be in a state of being integrally configured.

In the third embodiment to the seventh embodiment, for example, the first protrusion portion FL1B and the second protrusion portion FL2B may not have a flange shape, and may form the outer edges of the first fitted part Co1 and the second fitted part Co2, for example.

In the above embodiments, for example, the lengths of the first outer edge portion E1 and the second outer edge portion E2 may be relatively longer than, shorter than, or equal to the lengths of the third outer edge portion E3 and the fourth outer edge portion E4.

In each of the above embodiments, for example, the auxiliary member 8A or 8B may not be linear but may have other shapes such as an X-shaped member. The X-shaped member can be formed, for example, by punching a metal plate. The X-shaped member may be fixed to four arbitrary places of the frame FM1B, for example.

In each of the above embodiments, for example, the elastic member 9, 9B, 9D, or 9E may be in contact with or in proximity to a region different from the central region 7bsc of the back surface 7bs of the solar cell module 7 or 7F. In this case, for example, the elastic member 9, 9B, 9D, or 9E may be configured with two or more elastic members in contact with or in proximity to two or more regions sandwiching the central region 7bsc of the back surface 7bs of the solar cell module 7 or 7F.

In each of the above embodiments, for example, two or more auxiliary member 8, 8A, or 8B may be present or two or more elastic member 9, 9B, 9D, or 9E may be present for one solar cell module 7 or 7F.

In each of the above embodiments, for example, the elastic member 9, 9B, 9D, or 9E may include an elastic body other than elastomer such as a metal spring. However, even if the surface of the second protector 72 or the like is irregular, use of an elastic body of elastomer enables the elastic body to deform in accordance with the irregular surface, and enables concentration of stress to be less likely to occur.

In each of the above embodiments, for example, regardless of the magnitude relationship between the thickness of the first protector 71 and the thickness of the second protector 72, the positions of the plurality of solar cells 73c may be in a region closer to the back surface 7bs than the virtual center plane CL1 positioned at the center of the solar cell module 7 in the thickness direction. For example, by appropriately adjusting the distance between the first protector 71 and the plurality of solar cells 73c and the distance between the second protector 72 and the plurality of solar cells 73c, the plurality of solar cells 73c can be positioned in a region closer to the back surface 7bs than the virtual center plane CL1. Specifically, for example, in the sealing member 74 in the gap 7g, by appropriately adjusting the thickness of the part positioned between the first protector 71 and the plurality of solar cells 73c, and the thickness of the part positioned between the second protector 72 and the plurality of solar cells 73c, the plurality of solar cells 73c can be positioned in a region closer to the back surface 7bs than the virtual center plane CL1.

In each of the above embodiments, for example, the shapes of the front surface Ifs and the back surface 7bs of the solar cell module 7 or 7F may be quadrilateral other than rectangular such as trapezoidal or may be polygonal other than quadrilateral such as triangular, hexagonal, or octagonal.

It is needless to mention that all or part of each of the above embodiments and the variations can be combined as appropriate in a range not inconsistent.

1. A solar cell device comprising:
a solar cell module having a front surface and a back surface opposite the front surface, the front surface being convexly curved;
a first member supporting a first outer edge portion in a first direction along the back surface of the solar cell module;
a second member supporting a second outer edge portion opposite the first outer edge portion in the first direction of the solar cell module; and
an elastic member including an elastic body, and being in contact with the back surface or in proximity to the back surface, wherein
the solar cell module includes
a photoelectric converter
a first protector covering the photoelectric converter from a front surface side, and
a second protector covering the photoelectric converter from a back surface side.

2. The solar cell device according to claim 1, wherein
the elastic member is compressed on the back surface, and
the solar cell module has the front surface being convexly curved by an elastic force of the elastic member.

3. The solar cell device according to claim 2, wherein the elastic member is present in a state of pushing a central region of the back surface with an elastic force of the elastic body.

4. The solar cell device according to claim 1, further comprising an auxiliary member bridging between the first member and the second member and facing the back surface, wherein
the elastic member includes a part positioned between the auxiliary member and the back surface.

5. The solar cell device according to claim 4, wherein the auxiliary member is positioned in a state of linearly bridging between the first member and the second member.

6. The solar cell device according to claim 4, wherein the elastic member includes a part positioned on a central region of the auxiliary member in a longitudinal direction.

7. The solar cell device according to claim 6, wherein
the elastic member includes a part positioned along the longitudinal direction of the auxiliary member between the back surface and the auxiliary member, and includes a central part positioned on the central region, a first end part positioned on a first end part region closer to a first edge than to the central region in the longitudinal direction of the auxiliary member, and a second end part positioned on a second end region closer to a second edge opposite the first edge than to the central region in the longitudinal direction of the auxiliary member, and
the elastic member is in a state of being compressed by the back surface, and has a compression amount by the back surface in each of the first end part and the second end part larger than a compression amount by the back surface in the central part.

8. The solar cell device according to claim 6, wherein
the elastic member includes a part positioned along the longitudinal direction of the auxiliary member between the back surface and the auxiliary member, and includes a central part positioned on the central region, a first end part positioned on a first end region closer to a first edge than the central region in the longitudinal direction of the auxiliary member, and a second end part positioned on a second end region closer to a second edge opposite the first edge than the central region in the longitudinal direction of the auxiliary member, and
the elastic member is compressed by the back surface, and has a uniform compression ratio from the first end part to the second end part via the central part.

9. The solar cell device according to claim 4, wherein
the first member includes
a first groove portion into which the first outer edge portion is positioned in a state of being fitted and having a first recess that is recessed in the first direction,
a first wall portion positioned in a state of extending from the first groove portion along a third direction from the front surface to the back surface, and
a first protrusion portion positioned in a state of protruding along a second direction opposite the first direction from a part separated in the third direction from the first groove portion of the first wall portion, and including a first fitted part at an end portion close to the second member in the second direction,
the second member includes
a second groove portion into which the second outer edge portion is fitted and having a second recess that is recessed in the second direction,
a second wall portion positioned in a state of extending from the second groove portion along the third direction, and
a second protrusion portion positioned in a state of protruding along the first direction from a part separated in the third direction from the second groove portion of the second wall portion, and including a second fitted part at an end portion close to the first member in the first direction,
the auxiliary member includes a first fitting part positioned at an end portion close to the first member in the first direction, and a second fitting part positioned at an end portion close to the second member in the second direction,
the first fitting part is positioned in a state of being fixed to the first member, while being fitted into the first fitted part, and
the second fitting part is positioned in a state of being fixed to the second member, while being fitted into the second fitted part.

10. The solar cell device according to claim 1, wherein
the photoelectric converter includes a solar cell string that includes a plurality of solar cells arrayed along a fourth direction along the back surface orthogonal to the first direction, and one or more wires positioned in a state of electrically connecting the plurality of solar cells in series,
the solar cell module includes a sealing member that is filled, while covering the solar cell string, between the first protector and the second protector, the solar cell module having the front surface convexly curved along the first direction and a second direction opposite the first direction, and
the plurality of solar cells are positioned in a region closer to the back surface than a virtual center plane positioned at a center of the solar cell module in a thickness direction.

11. The solar cell device according to claim 10, wherein a thickness of the first protector is larger than a thickness of the second protector.

12. The solar cell device according to claim 1, wherein
the solar cell module has the front surface convexly curved along the first direction and a second direction opposite the first direction,
the second protector includes a first plate and a second plate that are made of chemically strengthened glass, and are adjacently arrayed in a fourth direction orthogonal to both the first direction and the second direction along the back surface, and
the elastic member is in contact with or in proximity to a part where the first plate and the second plate are adjacent to each other.

13. The solar cell device according to claim 1, further comprising:
a third member supporting a third outer edge portion in a fourth direction of the solar cell module, the fourth direction being orthogonal to both the first direction and a second direction opposite the first direction and along the back surface;
a fourth member supporting a fourth outer edge portion opposite the third outer edge portion in the fourth direction of the solar cell module;
a fifth member positioned between a region of a first central section of the third outer edge portion on the back surface and the third member when the third outer edge portion is virtually divided in the second direction into three, i.e., a part of a first section including a first end part, a part of a second section as the first central section including a central part, and a part of a third section including a second end part opposite the first end part; and
a sixth member positioned between a region of a second central section of the fourth outer edge portion on the back surface and the fourth member when the fourth outer edge portion is virtually divided in the second direction into three, i.e., a part of a fourth section including a third end part, a part of a fifth section as the second central section including a central part, and a part of a sixth section including a fourth end part opposite the third end part.

14. The solar cell device according to claim 13, wherein
the third member includes a third groove portion having a third recess into which the third outer edge portion is fitted and which is recessed in the fourth direction,
the third groove portion includes a first upper part positioned in a state of facing the front surface in the third outer edge portion and a first lower part positioned in a state of facing the back surface in the third outer edge portion,
the fifth member is positioned between a region of the second section of the third outer edge portion on the back surface and the first lower part,
the fourth member includes a fourth groove portion having a fourth recess in which the fourth outer edge portion is fitted and which is recessed in a fifth direction opposite the fourth direction,
the fourth groove portion includes a second upper part positioned in a state of facing the front surface in the fourth outer edge portion and a second lower part positioned in a state of facing the back surface in the fourth outer edge portion, and
the sixth member is positioned between a region of the fifth section of the fourth outer edge portion on the back surface and the second lower part,
the solar cell device further comprising:
a seventh member positioned between a region of the first section of the third outer edge portion on the front surface and the first upper part;
an eighth member positioned between a region of the third section of the third outer edge portion on the front surface and the first upper part;
a ninth member positioned between a region of the fourth section of the fourth outer edge portion on the front surface and the second upper part; and
a tenth member positioned between a region of the sixth section of the fourth outer edge portion on the front surface and the second upper part.

15. The solar cell device according to claim 1, wherein
the elastic body is present at a position being in a state of facing the back surface in the elastic member, and
a material of the elastic body contains elastomer.
